(19) United States
(12) Patent Application Publication
(10) Pub. No.: US 2011/0278662 A1
(43) Pub. Date: Nov. 17, 2011

(54) SEMICONDUCTOR DEVICE INCLUDING RECESSED CHANNEL TRANSISTOR AND METHOD OF MANUFACTURING THE SAME

(75) Inventors: Dong-il Park, Gyeongsangnam-do (KR); Joon-ho Cho, Seoul (KR); Tae-cheol Lee, Yongin-si (KR); Yong-sang Jeong, Hwaseong-si (KR); Eun-jeong Park, Hwaseong-si (KR); Young-mok Kim, Suwon-si (KR); Seok-ju Lee, Hwaseong-si (KR)

(73) Assignee: SAMSUNG ELECTRONICS CO., LTD., Suwon-si (KR)

(21) Appl. No.: 13/096,053

(22) Filed: Apr. 28, 2011

(30) Foreign Application Priority Data
May 11, 2010 (KR) 10-2010-0044053

(51) Int. Cl. H01L 29/78

(52) U.S. Cl. 257/330; 257/E29.262

(57) ABSTRACT

A semiconductor device including a recessed channel transistor, and a method of manufacturing the same, provide: a substrate in which an isolation trench is provided; an isolation layer provided in the isolation trench so as to define a pair of source/drain regions in the substrate; a gate pattern provided in the isolation trench between the pair of source/drain regions, the gate pattern having a top surface at a same level as a top surface of the isolation layer and having a bottom surface at a lower depth than the pair of source/drain regions with respect to a top surface of the substrate; and a gate insulating layer provided between the substrate and the gate pattern at a bottom surface of the isolation trench.

### CROSS-REFERENCE TO RELATED APPLICATION(S)

A claim of priority is made to Korean Patent Application No. 10-2010-0044053, filed on May 11, 2010 in the Korean Intellectual Property Office, the contents of which are incorporated herein by reference in their entirety.

### BACKGROUND

The inventive concept relates to a semiconductor device including a transistor, and more particularly, to a semiconductor device including a recessed channel transistor, and a method of manufacturing the same.

As the performance of semiconductor devices has rapidly improved, the speed thereof has rapidly become faster, the power consumption thereof has been rapidly reduced and the integration thereof has rapidly increased, recessed channel transistors have been suggested so as to improve characteristics of transistors.

With recessed channel transistors, recessed channel trenches are formed in regions that will be channels of the recessed channel transistors to increase lengths of the channels and to obtain sufficient lengths of the channels so as to prevent the lengths of the channels from being reduced due to a reduction in the size of semiconductor devices. In particular, high voltage transistors require high blocking voltage characteristics. Thus, even when widths of high voltage gates are reduced, recessed channel transistors with relatively long channels are employed to maintain advantageous electrical characteristics.

### SUMMARY

In order to obtain a contact area for supplying a voltage to a gate, relatively expensive, complicated processes, such as a photolithography process, an etching process, and the like, have been used in forming recessed channel transistors.

The inventive concept provides a semiconductor device including a recessed channel transistor that does not require relatively expensive, complicated processes used in a conventional semiconductor device to form the recessed channel transistor and easily obtains a contact region for supplying a voltage to a gate even when the gate has a relatively large width.

The inventive concept also provides a semiconductor device including a recessed channel transistor that provides a sufficient distance between a high-concentration drain region and a channel region, so as to prevent breakdown from occurring and to sustain a high breakdown voltage even when a high voltage is applied to a drain terminal in the recessed channel transistor used as a high voltage transistor.

The inventive concept also provides a method of manufacturing a semiconductor device including a recessed channel transistor that easily provides a contact region for supplying a voltage and provides a sufficient distance between a high-concentration drain region and a channel region, so as to sustain a high breakdown voltage.

According to an aspect of the inventive concept, there is provided a semiconductor device including: a substrate in which an isolation trench is provided; an isolation layer provided in the isolation trench so as to define a pair of source/drain regions in the substrate; a gate pattern provided in the isolation trench between the pair of source/drain regions, the gate pattern having a top surface at a same level as a top surface of the isolation layer and having a bottom surface at a lower depth than the pair of source/drain regions with respect to a top surface of the substrate; and a gate insulating layer provided between the substrate and the gate pattern at a bottom surface of the isolation trench.

The gate pattern may include: a gate portion positioned between the pair of source/drain regions; and at least one gate contact portion extending from the gate portion in a direction away from the pair of source/drain regions while being integrally formed with the gate portion as one contiguous unit, wherein a top surface of the gate portion and a top surface of the at least one gate contact portion are at the same level as the level of the top surface of the isolation layer.

The gate pattern may further include at least one gate contact plug connected to the at least one gate contact portion so as to apply a voltage to the gate portion.

The gate pattern may be formed in a gate trench formed through the isolation layer in the isolation trench, and an inlet width of the gate trench between the pair of source/drain regions may be less than an inlet width of the isolation trench.

The isolation layer may include a first isolation layer portion that covers the pair of source/drain regions as inner walls of the isolation trench, and the inlet width of the gate trench may be defined by the first isolation layer portion. The width of the gate trench at its inlet may be less than the width at the bottom surface of the gate trench.

Portions of the pair of source/drain regions exposed at the inner walls of the isolation trench may contact the first isolation layer, and portions of the pair of source/drain regions exposed at the bottom sidewalls of the isolation trench may contact the gate insulating layer.

The gate trench may include: a first gate trench portion in which the gate portion is positioned; and at least one second gate trench portion in which the at least one gate contact portion is positioned and which extends from the first gate trench portion in a direction away from the pair of source/drain regions while being in contact with the first gate trench portion, and wherein the gate portion completely fills the first gate trench portion on the gate insulating layer, and the at least one gate contact portion completely fills the at least one second gate trench portion on the gate insulating layer.

The gate portion and the at least one gate contact portion may have a “⊥”-shaped cross-section, respectively.

The gate pattern may include the gate portion and a plurality of gate contact portions, and the gate trench may include: a first gate trench portion in which the gate portion is positioned; and a plurality of second gate trench portions in which the plurality of gate contact portions are respectively positioned and which extend from the first gate trench portion in a direction away from the pair of source/drain regions while being in contact with the first gate trench portion, and wherein the gate portion completely fills remaining portions of the first gate trench portion excluding an inlet center of the first gate trench portion on the gate insulating layer, and the plurality of gate contact portions completely fill the plurality of second gate trench portions on the gate insulating layer. The gate portion may have a “ [symbol] ”-shaped cross-section.

The plurality of gate contact portions may be arranged in a line in a first direction, and the plurality of gate contact portions may extend from the gate portion in a gear tooth shape.

The semiconductor device may further include an insulating layer filling the inlet center of the first gate trench portion on the gate portion.

According to another aspect of the inventive concept, there is provided a semiconductor device including: a substrate in which an isolation trench is provided; an isolation layer provided in the isolation trench so as to define a pair of source/drain regions in the substrate; a gate pattern provided in a gate trench formed through the isolation layer in an isolation trench, the gate trench having a top surface at a same level as a top surface of the isolation layer and comprising a gate portion positioned between the pair of source/drain regions in the gate trench, and at least one gate contact portion extending from the gate portion in a direction away from the gate portion while being integrally formed with the gate portion as one contiguous unit in the gate trench; and a gate insulating layer provided between the substrate and the gate pattern.

According to another aspect of the inventive concept, there is provided a method of manufacturing a semiconductor device, the method including: A method of manufacturing a semiconductor device, the method comprising: forming an isolation trench between a pair of first regions that are separated from each other in a substrate; forming an isolation layer in the isolation trench; forming a pair of source/drain regions in the pair of first regions of the substrate; forming in the isolation trench a gate trench having an extended lower portion with a larger width than a width of an inlet of the gate trench at an upper portion of the gate trench, and exposing the substrate in the extended lower portion, by removing portions of the isolation layer so that remaining portions of the isolation layer remain in the isolation trench; forming a gate insulating layer on a surface of the substrate exposed in the gate trench; and forming a gate pattern having a top surface at the same level as a level of a top surface of remaining portions of the isolation layer on the gate insulating layer in the gate trench.

The forming of the gate trench may include: forming a mask pattern for exposing portions of the isolation layer on the pair of source/drain regions and the isolation layer; forming an inlet at an upper portion of the gate trench in which the isolation layer is exposed at sidewalls and a bottom surface of the gate trench, by anisotropically etching portions of the isolation layer by using the mask pattern as an etch mask; forming a mask spacer at inner sidewalls of the inlet of the gate trench; forming an extended lower portion of the gate trench for exposing the substrate by isotropically etching the isolation layer exposed in the inlet of the gate trench by using the mask pattern and the mask spacer as an etch mask; and removing the mask pattern and the mask spacer.

The inlet of the gate trench, after the extended lower portion of the gate trench is formed, may be surrounded by the remaining portions of the isolation layer.

After the extended lower portion of the gate trench is formed, portions of the pair of source/drain regions may be exposed in the extended lower portion of the gate trench.

The removing of the mask pattern and the mask spacer may be performed using an isotropic etching process.

The gate trench may include: a first gate trench portion positioned between the pair of source/drain regions; and at least one second gate trench portion extending from the first gate trench portion in a direction away from the pair of source/drain regions while communicating with the first gate trench portion.

The gate trench may include a plurality of second gate trench portions extending from the first gate trench portion in a gear tooth shape, and the plurality of second gate trench portions are arranged in a line in a first direction.

The gate pattern may include: a gate portion positioned in the first gate trench portion; and at least one gate contact portion positioned in the at least one second gate trench portion. The gate portion may completely fill the first gate trench portion on the gate insulating layer, and the at least one gate contact portion may completely fill the at least one second gate trench portion on the gate insulating layer.

The method may further include, after the gate pattern is formed, respectively forming at least one contact plug for supplying a voltage to the gate portion in the at least one gate contact portion.

The forming of the gate pattern may include: forming a gate conductive layer having a first thickness on the substrate inside the gate trench and outside the gate trench; and planarizing the gate conductive layer until a top surface of the remaining portions of the isolation layer is exposed so that the gate conductive layer remains only in the gate trench.

According to another aspect of the inventive concept, there is provided a method of manufacturing a semiconductor device, the method including: A method of manufacturing a semiconductor device, the method comprising: forming an isolation trench between a pair of first regions that are separated from each other in a substrate; forming an isolation layer in the isolation trench; forming a pair of source/drain regions in the pair of first regions of the substrate; forming a gate trench comprising a first gate trench portion positioned between the pair of source/drain regions, and at least one second gate trench portion extending from the first gate trench portion in a direction away from the pair of source/drain regions while being on contact with the first gate trench portion, by removing portions of the isolation layer so that remaining portions of the isolation layer remain in the isolation trench; forming a gate insulating layer on a surface of the substrate exposed in the gate trench; and forming a gate pattern having a top surface at the same level as a level of a top surface of remaining portions of the isolation layer on the gate insulating layer in the gate trench.

### BRIEF DESCRIPTION OF THE DRAWINGS

Exemplary embodiments of the inventive concept will be more clearly understood from the following detailed description taken in conjunction with the accompanying drawings in which:

FIGS. 1A-B through FIGS. 14A-B illustrate a method of manufacturing a semiconductor device according to an embodiment of the inventive concept. In particular, FIGS. 1A, 2A, . . . , and 14A are respectively plan views for explaining the method of manufacturing a semiconductor device illustrated in FIGS. 1A-1B through FIGS. 14A-B, and FIGS. 1B, 2B, . . . , and 14B are cross-sectional views taken along lines BX-BX′ and BY-BY′ of FIGS. 1A, 2A, . . . , and FIG. 14A, respectively;

FIGS. 15A-C through FIGS. 24A-C illustrate a method of manufacturing a semiconductor device according to another embodiment of the inventive concept. In particular, FIGS. 15A, 16A, . . . , and 24A are respectively plan views for explaining the method of manufacturing a semiconductor device illustrated in FIGS. 15A-C through FIGS. 24A-C, and FIGS. 15B, 16B, . . . , and 24B are cross-sectional views taken along lines BX-BX′ of FIGS. 15A, 16A, . . . , and 24A, and FIGS. 15C, 16C, . . . , and 24C are cross-sectional views taken along lines BY1-BY1′ and BY2-BY2′ of FIGS. 15A, 16A, . . . , and FIG. 24A, respectively;

FIGS. 25A, 25B, and 25C illustrate relevant portions of a structure of a semiconductor device according to another embodiment of the inventive concept. In particular, FIG. 25A is a plan view of a recessed channel transistor including a gate pattern having five gate contact portions, and FIG. 25B is a cross-sectional view taken along a line BX-BX′ of FIG. 25A, and FIG. 25C is a cross-sectional view taken along lines BY1-BY1′ and BY2-BY2′ of FIG. 25A, respectively;

FIG. 26 is a schematic block diagram of a display driver integrated circuit (IC) (DDI), and a display apparatus including the DDI, according to an embodiment of the inventive concept;

FIG. 27 is a schematic block diagram of an electronic system according to an embodiment of the inventive concept; and

FIG. 28 is a schematic block diagram of a memory card according to an embodiment of the inventive concept.

### DETAILED DESCRIPTION OF THE EMBODIMENTS

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity. Also, various elements and regions in the drawings are schematically marked. Thus, the inventive concept is not limited to relative sizes or distances drawn in the accompanying drawings. Like reference numerals in the drawings denote like elements, and thus their description will be omitted.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

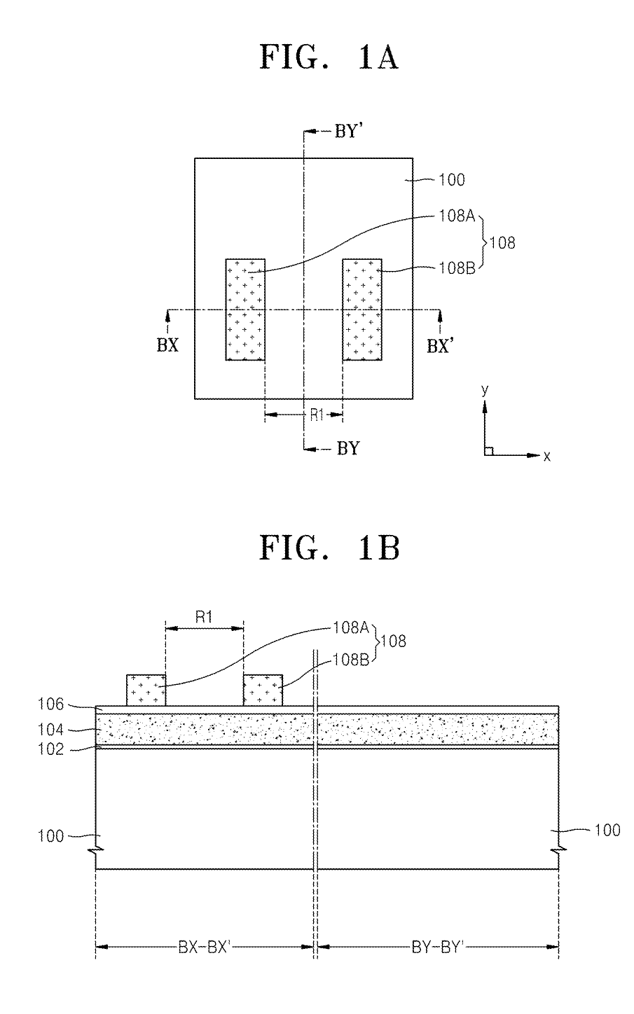

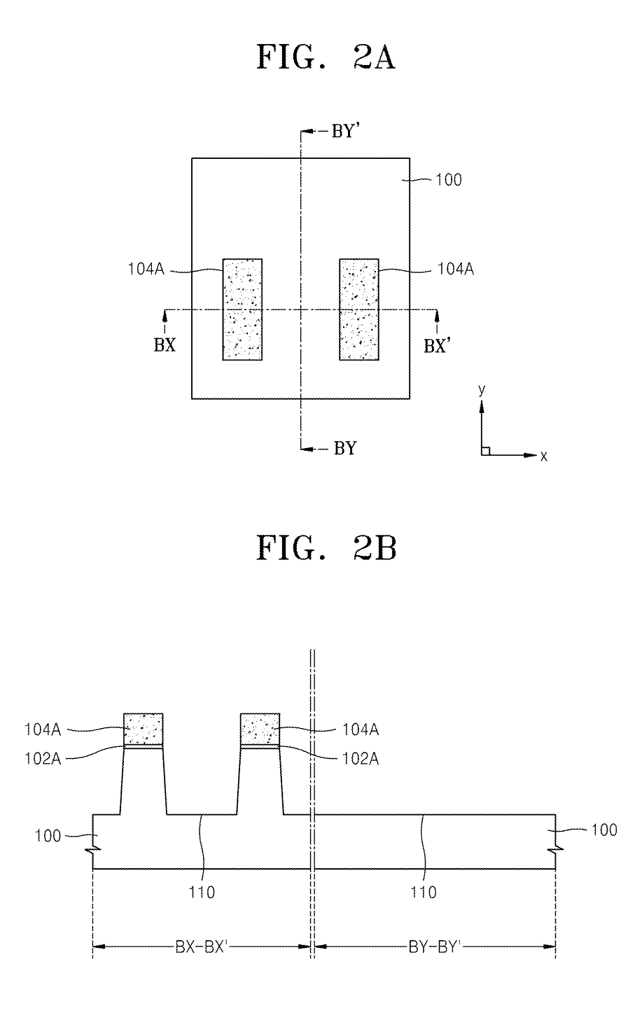

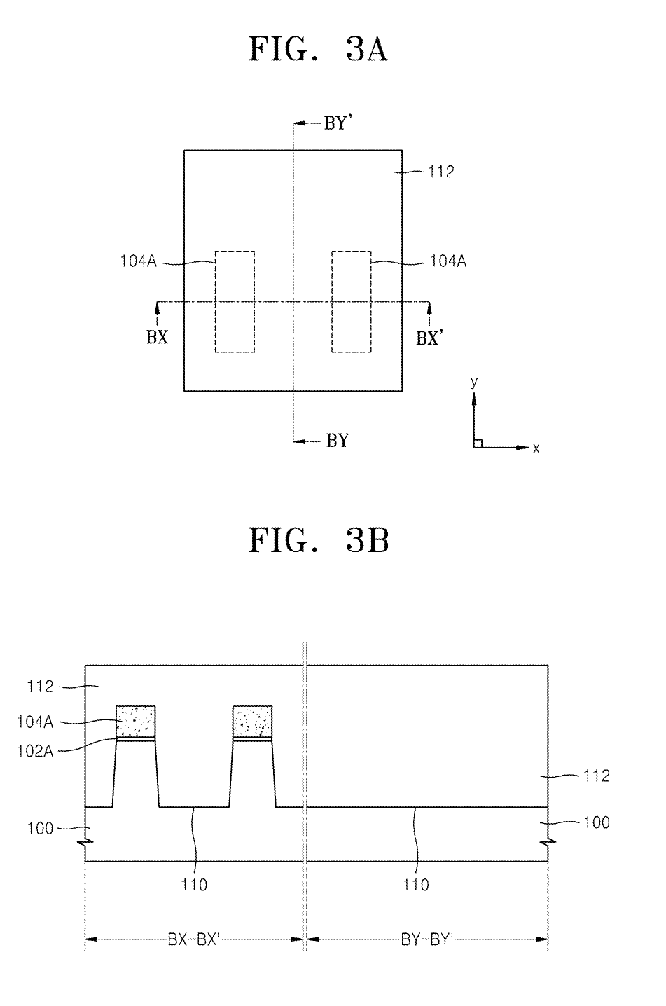

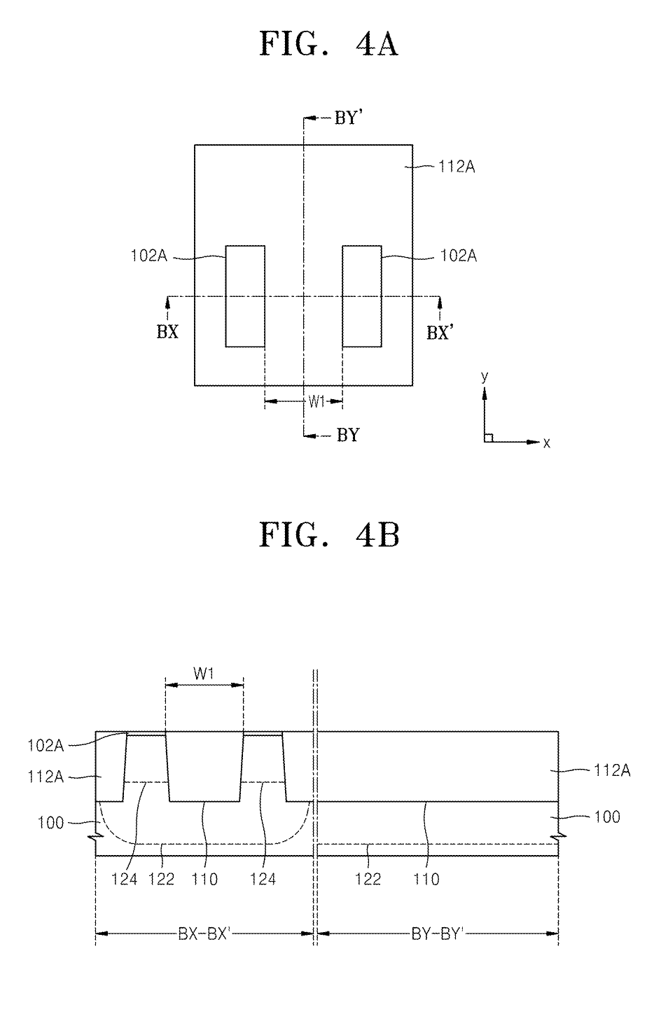

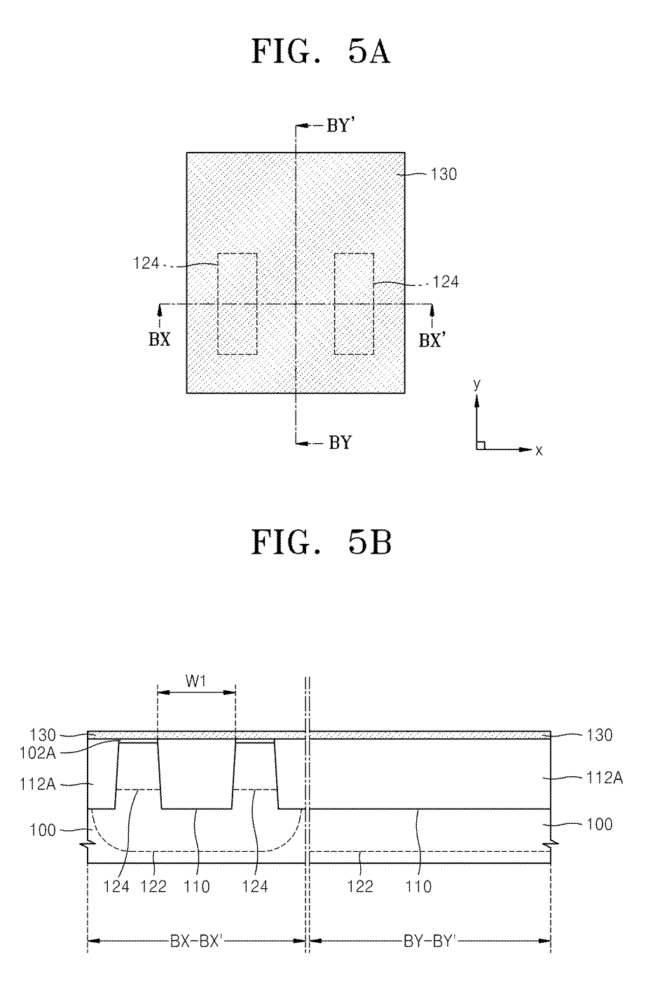

FIGS. 1A-B through FIGS. 14A-B illustrate a method of manufacturing a semiconductor device, according to an embodiment of the inventive concept.

In particular, FIGS. 1A, 2A, . . . , and 14A are respectively plan views for explaining the method of manufacturing a semiconductor device illustrated in FIGS. 1A-B through FIGS. 14A-B, and FIGS. 1B, 2B, . . . , and 14B are cross-sectional views taken along lines BX-BX′ and BY-BY′ of FIGS. 1A, 2A, . . . , and FIG. 14A, respectively.

Referring to FIGS. 1A and 1B, a pad oxide layer 102, a first mask layer 104, an anti-reflective layer 106, and a photoresist pattern 108 are sequentially formed in the order stated on a substrate 100.

A top surface of anti-reflective layer 106 is partially exposed around photoresist pattern 108.

Substrate 100 may be a semiconductor substrate, such as a silicon substrate. First mask layer 104 may be a silicon oxide layer. Anti-reflective layer 106 may be an organic or inorganic anti-reflective layer. For example, anti-reflective layer 106 may be formed of silicon oxynitride (SiON).

Photoresist pattern 108 may include two patterns 108A and 108B that cover corresponding areas of substrate 100 where a pair source/drain regions 124 (see FIG. 4B, discussed below) of a transistor are to be formed. Patterns 108A and 108B may be separated from each other in a gate length direction (x-direction of FIG. 1A) by a first distance R1 that corresponds to a distance at which the pair of source/drain regions 124 are separated from each other.

As occasion demands, after pad oxide layer 102 is formed on substrate 100, before first mask layer 104 is formed, an ion implantation process for forming wells in substrate 100 may be performed. Also, after pad oxide layer 102 is formed and before first mask layer 104 is formed, an ion implantation process for forming channel regions in substrate 100 may be performed. The ion implantation process, which will be described later, for forming wells and the ion implantation process for forming channel regions may also be performed after a process of forming an isolation layer 112A (discussed below with reference to FIGS. 4A and 4B) is performed.

Referring to FIGS. 2A and 2B, anti-reflective layer 106, first mask layer 104, and pad oxide layer 102 are etched using photoresist pattern 108 as an etch mask to form an anti-reflective pattern (not shown), a first mask pattern 104A, and a pad oxide layer pattern 102A, thereby exposing a top surface of substrate 100. Subsequently, the exposed substrate 100 is etched using the anti-reflective pattern (not shown) and first mask pattern 104A as an etch mask, thereby forming isolation trenches 110.

After that, photoresist pattern 108 that remains on first mask pattern 104A and the anti-reflective pattern (not shown) are removed until a top surface of first mask pattern 104A is exposed.

Referring to FIGS. 3A and 3B, an insulating layer 112 is formed on substrate 100 and first mask pattern 104A so that insulating layer 112 completely fills isolation trenches 110.

Insulating layer 112 may include a sidewall oxide layer (not shown) that covers inner walls of isolation trenches 110, a nitride layer liner (not shown) that covers the sidewall oxide layer, and a gap-fill oxide layer (not shown) that completely fills internal spaces of isolation trenches 110.

Referring to FIGS. 4A and 4B, first mask pattern 104A and a portion of insulating layer 112 are removed by a planarization process until pad oxide layer pattern 102A is exposed, thereby forming isolation layer 112A from the remaining parts of insulating layer 112 in trenches 110. To perform the planarization process, a chemical mechanical polishing (CMP) process may be used. Source/drain regions 124 are defined in substrate 100 by isolation layer 112A.

After isolation layer 112A is formed, pad oxide layer pattern 102A may remain on the top surface of substrate 100. Although not shown, pad oxide layer pattern 102A may be used during the planarization process as occasion demands. In this case, a new pad oxide layer (not shown) may be formed on the top surface of substrate 100.

Subsequently, the ion implantation process is performed on substrate 100 by using an ion implantation mask (not shown) a plurality of times if necessary, thereby forming a channel ion implantation region 122 and the pair of source/drain regions 124 in substrate 100.

Isolation layer 112A having a first width W1 in a first direction which is the gate length direction (x-direction in FIG. 4A) is formed between the pair of source/drain regions 124. Thus, a distance by which the pair of source/drain regions 124 are separated from each other in the first direction (x-direction in FIG. 4A) is equal to the first width W1.

Referring to FIGS. 5A and 5B, a second mask layer 130 is formed on substrate 100 and completely covers isolation layer 112A and pad oxide layer pattern 102A.

Second mask layer 130 may be a silicon nitride layer.

Referring to FIGS. 6A and 6B, a third mask pattern 132, in which holes 132H for partially exposing second mask layer 130 is formed, is formed on second mask layer 130.

Third mask pattern 132 may be a photoresist pattern. Alternatively, third mask pattern 132 may be a hard mask pattern formed of a material having a different etch selectivity from that of second mask layer 130 and isolation layer 112A.

Each of the holes 132H of third mask pattern 132 exposes portions of second mask layer 130 that are formed directly on isolation layer 112A between the pair of source/drain regions 124.

Each of the holes 132H includes a first hole portion 132H1 that is formed in an upper portion of a gate region between the pair of source/drain regions 124 of substrate 100, and a second hole portion 132H2 that is formed in an upper portion of a gate contact region of substrate 100 and extends from first hole portion 132H1 in a direction away from the pair of source/drain regions 124 while communicating with (i.e., being connected to) first hole portion 132H1.

First hole portion 132H1 of each of holes 132H formed in third mask pattern 132 has a second width W2 that is less than the first width W1 in the first direction (x-direction in FIG. 6A). Around first hole portion 132H1, portions of isolation layer 112A that are between the pair of source/drain regions 124 are covered by third mask pattern 132 have a third width W3 and a fourth width W4 in the first direction (x-direction in FIG. 6A). Second width W2 is in of a similar dimension as the first width W1, and the sum of the second width W2, the third width W3, and the fourth width W4 may be the first width W1. In this regard, first hole portion 132H1 is positioned in the center of isolation layer 112A between the pair of source/drain regions 124 so that the third width W3 and the fourth width W4 may be the same. However, aspects of the inventive concept are not limited thereto. As occasion demands, the third width W3 and the fourth width W4 may have different dimensions according to the position of first hole portion 132H1 between the pair of source/drain regions 124.

Referring to FIGS. 7A and 7B, second mask layer 130 is anisotropically etched using third mask pattern 132 as an etch mask, thereby forming a second mask pattern 130A for exposing portions of isolation layer 112A. Subsequently, isolation layer 112A exposed around second mask pattern 130A is anisotropically etched, thereby forming a gate trench 140 in isolation layer 112A.

After that, third mask pattern 132 that remains on second mask pattern 130A is removed until a top surface of second mask pattern 130A is exposed.

Gate trench 140 has a depth that is less than that of isolation trench 110. In particular, a distance from the top surface of substrate 100 where source/drain regions 124 are formed to a bottom surface of gate trench 140 is less than a distance from the top surface of substrate 100 where source/drain regions 124 are provided to a bottom surface of isolation trench 110. Thus, only isolation layer 112A may be exposed as inner walls of gate trench 140.

Gate trench 140 includes a first gate trench portion 140T1 in which a gate portion 152G (see FIGS. 12A and 12B, discussed below) between the pair of source/drain regions 124 of substrate 100 is to be disposed, and a second gate trench portion 140T2 in which a gate contact portion 152C (see FIGS. 12A and 12B, discussed below) is to be disposed and which extends from first gate trench portion 140T1 in a direction away from the pair of source/drain regions 124, while communicating with (i.e., being in contact with) first gate trench portion 140T1.

Referring to FIGS. 8A and 8B, a mask spacer 142 is formed on inner sidewalls of gate trench 140.

In order to form mask spacer 142, a fourth mask layer (not shown) that covers the entire surface of a resultant structure formed by gate trench 140 to a uniform thickness is formed. Then, the entire surface of the fourth mask layer is etched back until the bottom surface of gate trench 140 is exposed, so that mask spacer 142 may remain only on the inner sidewalls of gate trench 140. The mask spacer 142 may be formed of silicon nitride (SiN).

Mask spacer 142 may be formed to cover isolation layer 112A, i.e., the inner sidewalls of gate trench 140, to a thickness of about 100 to 200 Å.

Referring to FIGS. 9A and 9B, isolation layer 112A exposed by mask spacer 142 is removed from an inside of gate trench 140 by using an isotropic etching process using wet etching, thereby increasing the dimension or extent of a lower part of gate trench 140 in both vertical and horizontal directions to form a lower portion 140BT of gate trench 140. While the wet etching process is performed, second mask pattern 130A and mask spacer 142 may be used as an etch mask.

While the wet etching process is performed on isolation layer 112A exposed by mask spacer 142, isotropic etching is performed on isolation layer 112A exposed on the bottom surface of gate trench 140 in the directions shown by the arrows in FIG. 9B. As a result, lower portion 140BT of gate trench 140 which is extended in both vertical and horizontal directions is obtained. Portions of the pair of source/drain regions 124 are exposed in lower portion 140BT of gate trench 140. Portions of isolation layer 112A that cover source/drain regions 124 and are close to the top surface of substrate 100 where source/drain regions 124 are provided are protected by mask spacer 142 on inner walls of isolation trench 110 and are not removed during the wet etching process and remain as remaining portions 112B of isolation layer 112A. Due to remaining portions 112B of isolation layer 112A that cover source/drain regions 124 on the inner walls of isolation trench 110, an inlet width of gate trench 140 is limited, and the inlet width of gate trench 140 is less than a width of the bottom surface of gate trench 140. Due to remaining portions 112B of isolation layer 112A, a separation distance between an internal space of gate trench 140 and top surfaces of source/drain region 124 may be obtained.

In FIG. 9A, a planar shape of lower portion 140BT that extends in vertical and horizontal directions is indicated by a dashed line.

In order to perform the wet etching process on isolation layer 112A, a fluorine (F)-containing etchant, for example, an etchant formed of diluted hydrogen fluoride (HF) (DHF), NH₄F or a combination thereof, may be used.

Referring to FIGS. 10A and 10B, first mask pattern 130A and mask spacer 142 are removed.

A wet etching process may be used to remove first mask pattern 130A and mask spacer 142. When each of first mask pattern 130A and mask spacer 142 is a silicon nitride layer, a wet etching process using a phosphoric acid solution may be used to remove first mask pattern 130A and mask spacer 142.

Referring to FIGS. 11A and 11B, an insulating layer is formed on the surface of substrate 100 exposed in lower portion 140BT of gate trench 140, as a gate insulating layer 150A, and a gate conductive layer 152 fills gate trench 140 and covers gate insulating layer 150A.

When gate conductive layer 152 is formed in gate trench 140 and on substrate 100 to a uniform thickness, the width GX1 of first gate trench portion 140T1 of gate trench 140 and the width GX2 of second gate trench portion 140T2 of gate trench 140 in the first direction (x-direction in FIG. 11A) are relatively less than a deposition thickness of gate conductive layer 152 so that the internal space of gate trench 140 may be completely filled by gate conductive layer 152.

If the width GX1 of first gate trench portion 140T1 of gate trench 140 is increased in the first direction (x-direction in FIG. 11A), after gate conductive layer 152 is formed with a uniform thickness in gate trench 140, there may be an empty space in gate conductive layer 152 from the inside of gate trench 140 to an inlet center of gate trench 140, which will be described later in another embodiment of the inventive concept.

Insulating layer 150 that constitutes gate insulating layer 150A may be a silicon oxide layer, for example.

Gate conductive layer 152 may be formed of an electrically conductive material. Gate conductive layer 152 may be formed of doped polysilicon, metal, metal nitride, metal silicide or a combination thereof.

Referring to FIGS. 12A and 12B, gate conductive layer 152 is planarized until isolation layer 112A and remaining portions 112B of isolation layer 112A are exposed, thereby forming a gate pattern 152A only in gate trench 140.

Gate pattern 152A includes gate portion 152G that is positioned in first gate trench portion 140T1 and functions as a gate electrode between the pair of source/drain regions 124, and gate contact portion 152C that is positioned in second gate trench portion 140T2 and extends from gate portion 152G in a direction away from the pair of source/drain regions 124 while being integrally formed with gate portion 152G as one contiguous unit. A bottom surface of gate pattern 152A is at a lower level than the bottom of the pair of source/drain regions 124 with respect to the top surface of substrate 100 where source/drain regions 124 are provided. Thus, a distance from the top surface of substrate 100 where source/drain regions 124 are provided to the bottom surface of gate portion 152G is greater than a distance from the top surface of substrate 100 where source/drain regions 124 are provided to the bottom of the pair of source/drain regions 124.

The planarized top surface of gate pattern 152A including gate portion 152G and gate contact portion 152C may be at the same level as the top surface of isolation layer 112A and the top surface of remaining portions 112B of isolation layer 112A.

As illustrated in FIG. 12B, gate portion 152G of gate pattern 152A may be “⊥”-shaped when viewing a cross-section taken in the first direction (x-direction in FIG. 11A). Gate contact portion 152C of gate pattern 152A also may be “⊥”-shaped when viewing a cross-section taken in a direction parallel to the first direction (x-direction in FIG. 11A.

If the width of first gate trench portion 140T1 of gate trench 140 is increased in the first direction (x-direction in FIG. 11A), a cross-sectional shape taken in the first direction of gate portion 152G may vary. This will be described later in another embodiment.

Top portions of the pair of source/drain regions 124 exposed at the inner sidewalls of isolation trench 110 contact remaining portions 112B of isolation layer 112A, and bottom portions of the pair of source/drain regions 124 exposed at the inner sidewalls of isolation trench 110 contact gate insulating layer 150A.

Due to remaining portions 112B of isolation layer 112A that cover source/drain regions 124 as the inner sidewalls of first gate trench portion 140T1 of gate trench 140, a separation distance between gate portion 152G of gate pattern 152A and top surfaces of source/drain regions 124 may be obtained.

Referring to FIGS. 13A and 13B, an interlayer insulating layer 160 is formed on the resultant structure in which gate pattern 152A is formed, and interlayer insulating layer 160 and portions of pad oxide layer pattern 102A under interlayer insulating layer 160 are anisotropically etched, thereby forming a plurality of contact holes 160H formed through interlayer insulating layer 160.

The plurality of contact holes 160H may include a gate contact hole 160H1 for exposing gate contact portion 152C, and a pair of source/drain contact holes 160H2 for respectively exposing portions of the top surfaces of the pair of source/drain regions 124.

Referring to FIGS. 14A and 14B, a plurality of contact plugs 170 are formed in the plurality of contact holes 160H.

The plurality of contact plugs 170 may include a gate contact plug 170G connected to gate contact portion 152C, and a pair of source/drain contact plugs 170C respectively connected to the top surfaces of the pair of source/drain regions 124.

In order to form the plurality of contact plugs 170, after a conductive material is deposited on the device including interlayer insulating layer 160 to completely fill contact holes 160H and form a conductive layer, the conductive layer is planarized using a planarizing process until a top surface of interlayer insulating layer 160 is exposed. In order to perform the planarization process, a CMP process may be used.

Contact plugs 170 may be formed of an electrically conductive material. Contact plugs 170 may be formed of metal, metal silicide, metal nitride or a combination thereof.

After that, although not shown, metal interconnection layers respectively connected to contact plugs 170 may be formed on interlayer insulating layer 160.

In the semiconductor device manufactured using the method illustrated in FIGS. 1A-B through FIGS. 14A-B, gate portion 152G of gate pattern 152A is at a lower level than the top surface of substrate 100 where the source/drain regions 124 are provided, and thus a transistor having a recessed channel structure is formed. Thus, the channel length of the transistor may be remarkably increased. Even in the case of a highly integrated semiconductor device, stable device characteristics may be obtained. Also, gate contact portion 152C to which gate contact plug 170G for applying a voltage to gate portion 152G is connected is a part of gate pattern 152A having a planarized top surface at the same level as that of the top surface of isolation layer 112A. In this way, gate contact portion 152C is formed simultaneously with gate portion 152G. Thus, an additional process for forming gate contact portion 152C is not necessary. Accordingly, a method of manufacturing a semiconductor device, which includes a process of forming a recessed channel transistor, may be simplified.

Also, due to remaining portions 112B of isolation layer 112A that cover the pair of source/drain regions 124 as the inner walls of first gate trench portion 140T1 of gate trench 140, a separation distance between gate portion 152G of gate pattern 152A and source/drain contact plugs 170C connected to the top surfaces of pair of source/drain regions 124 may be obtained. Thus, even when a high voltage is applied to a drain terminal of the pair of source/drain regions 124, a sufficient distance between a drain region and a recessed channel region is obtained so that breakdown may be prevented and a high breakdown voltage may be sustained.

In the method of manufacturing a semiconductor device illustrated in FIGS. 1A-B through FIGS. 14A-B, the length of gate portion 152G in the channel direction, that is, the gate length, is relatively small, and one gate contact portion 152C extends from the gate portion 152G of the gate pattern 152A, and one gate contact plug 170G is connected to the gate pattern 152A. However, aspects of the inventive concept are not limited thereto. The semiconductor device and the method of manufacturing a semiconductor device according to the above-described embodiments of the inventive concept may be applied to a method of forming a recessed channel transistor having a relatively large gate length in which a plurality of gate contact plugs are connected to a gate pattern.

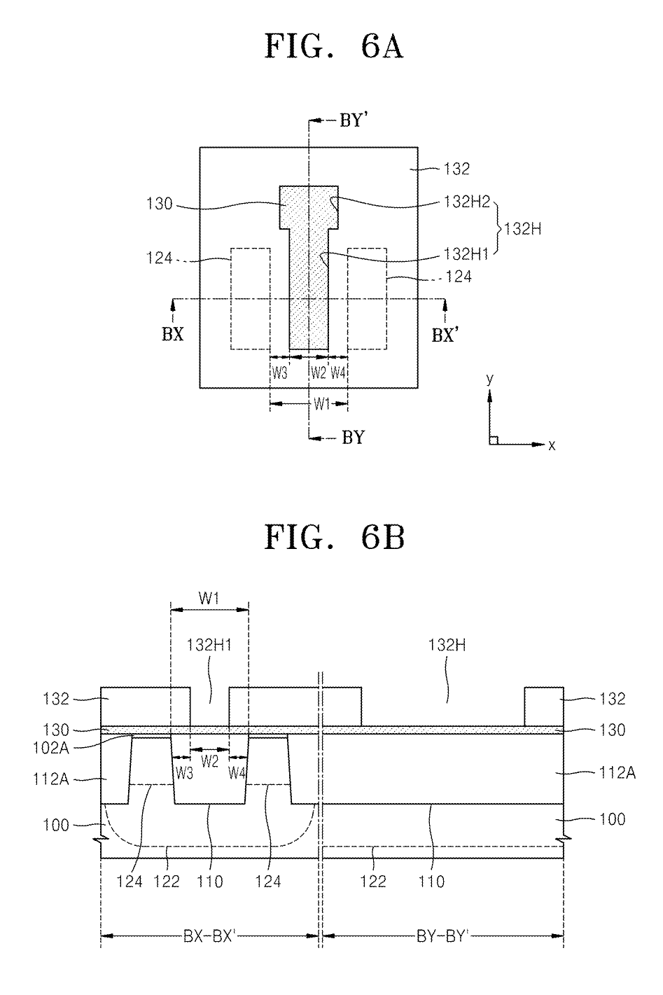

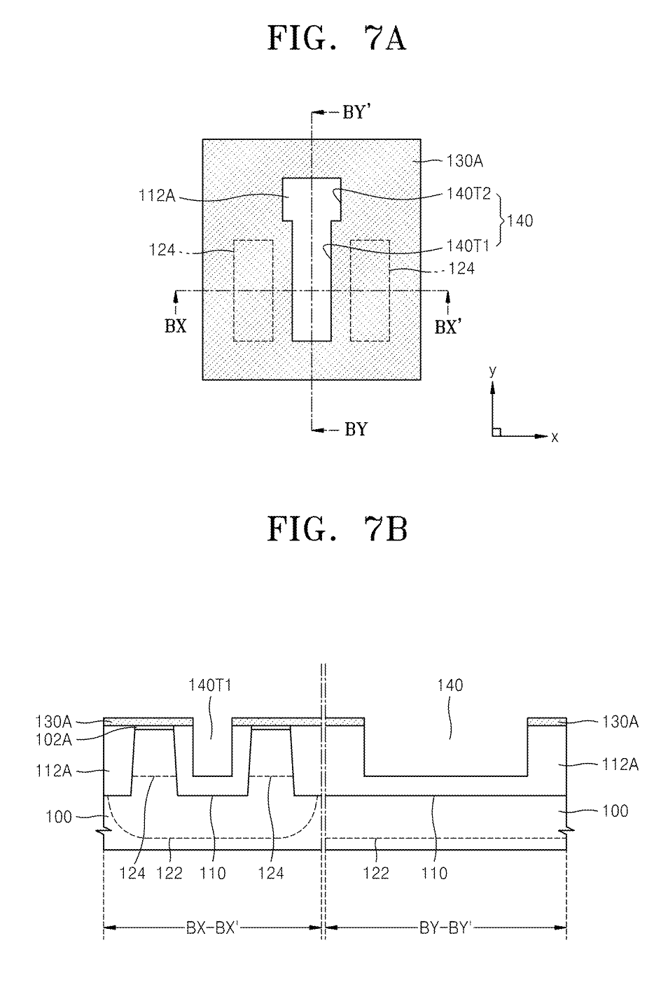

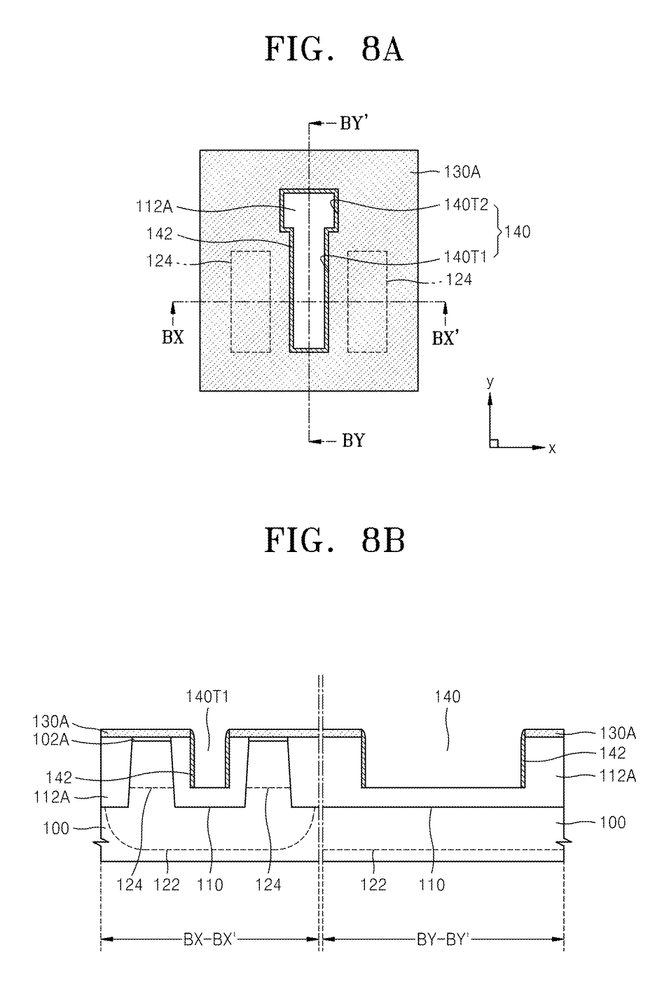

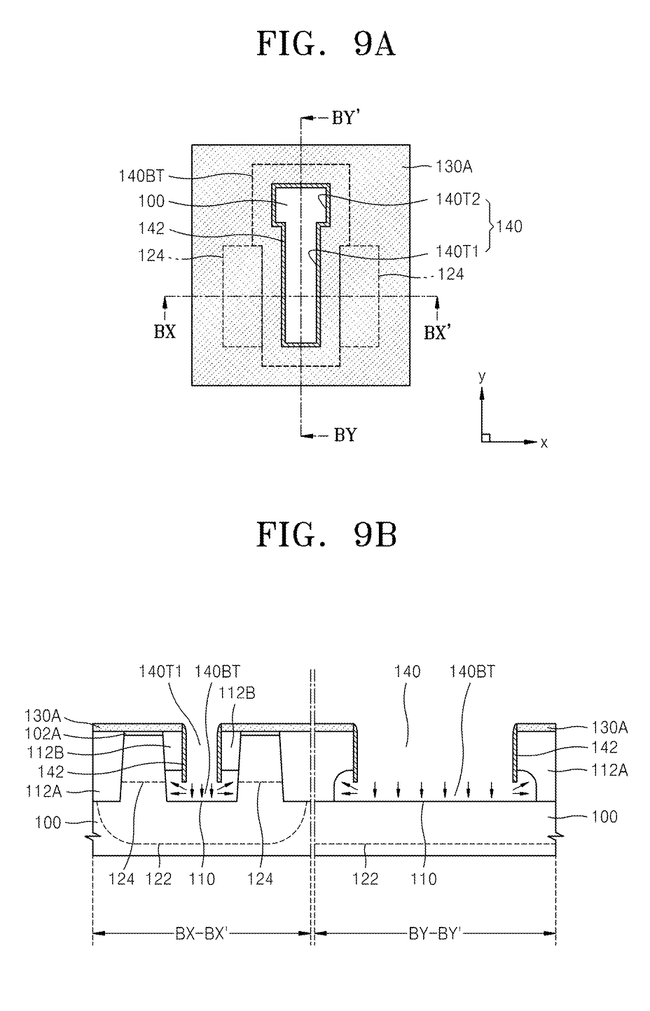

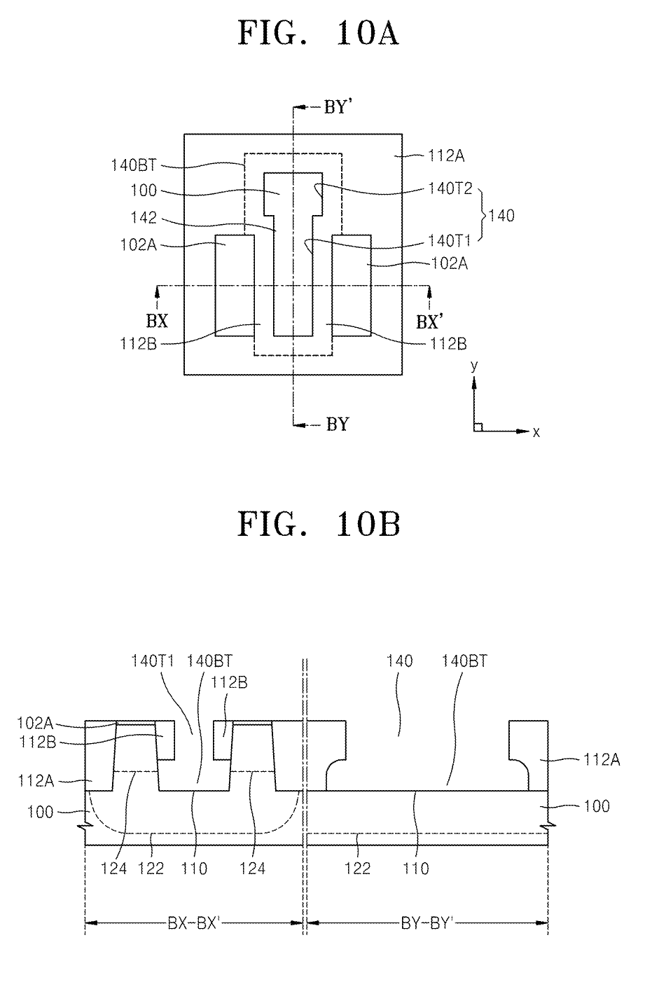

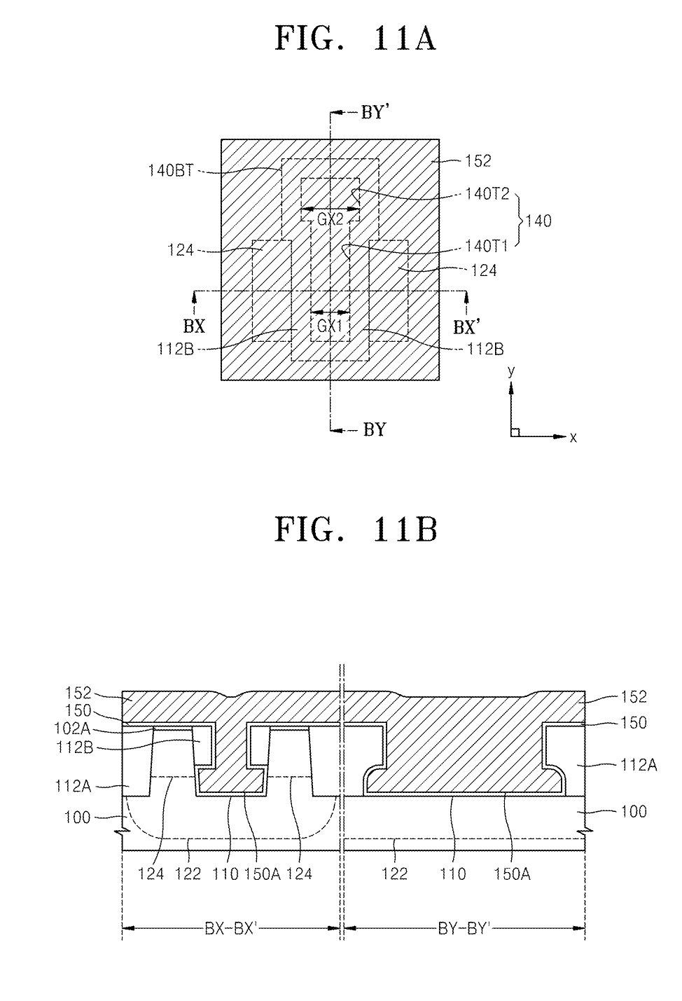

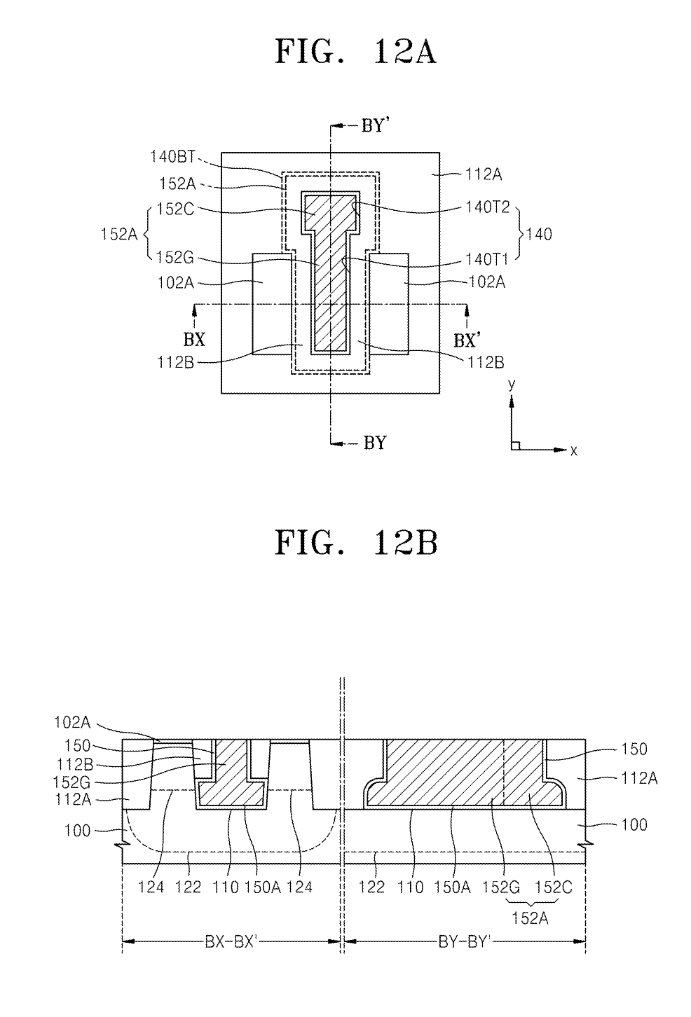

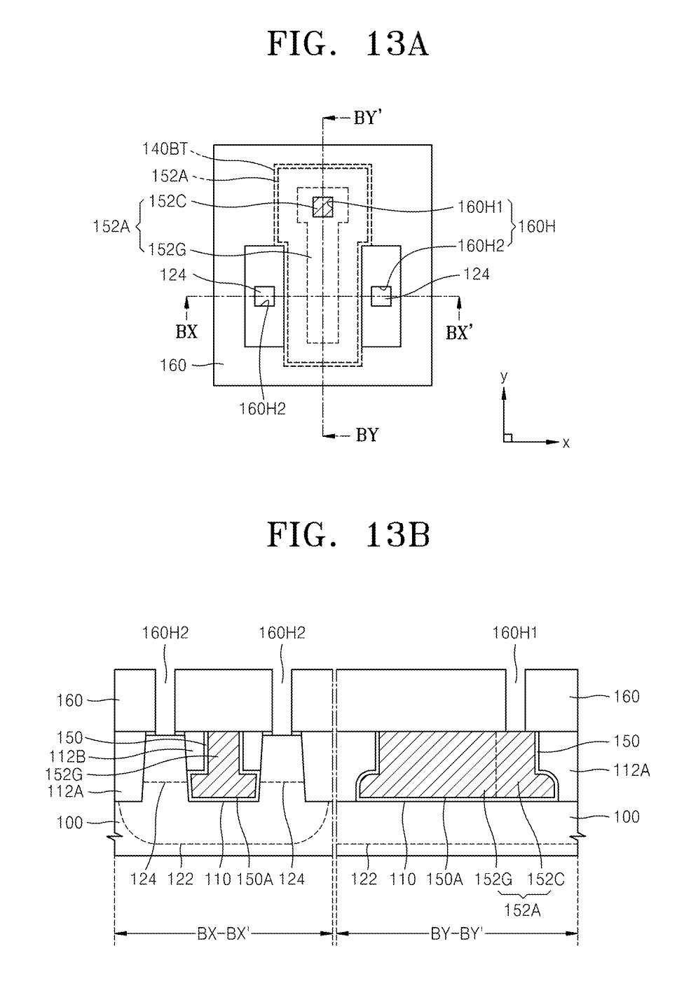

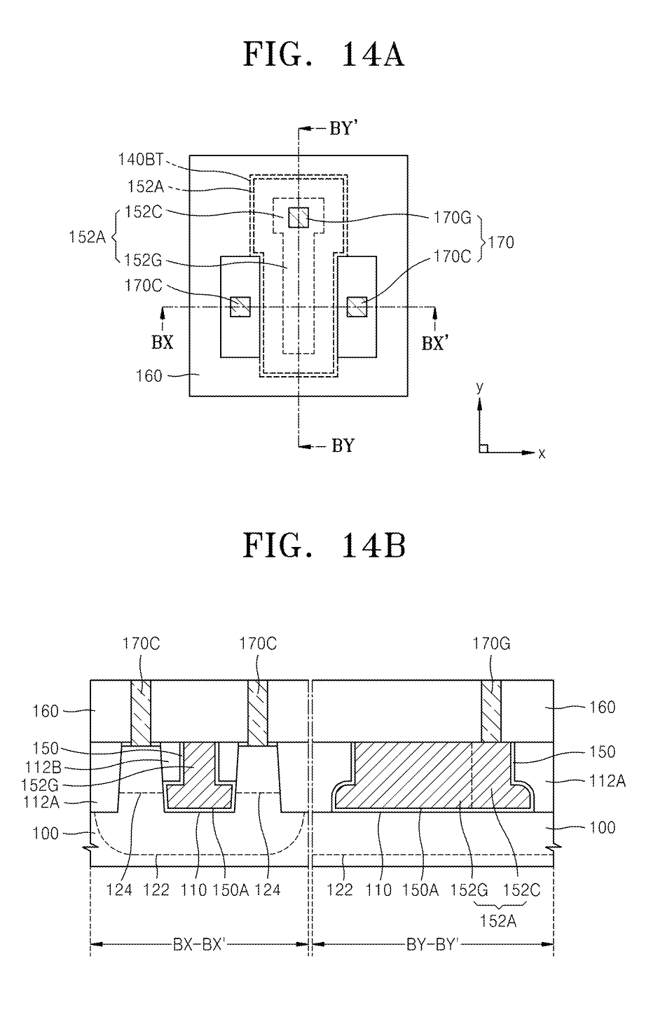

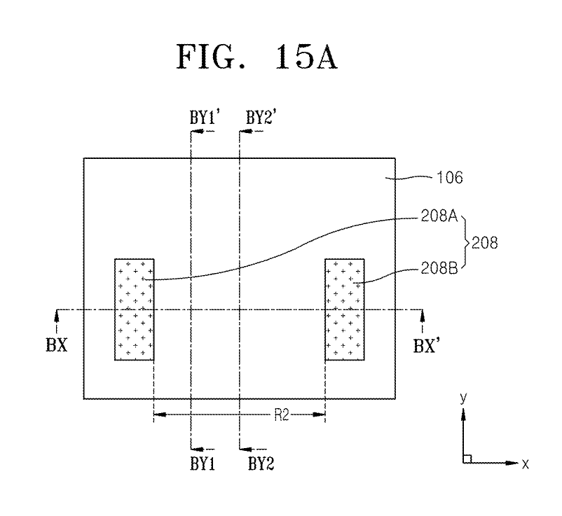

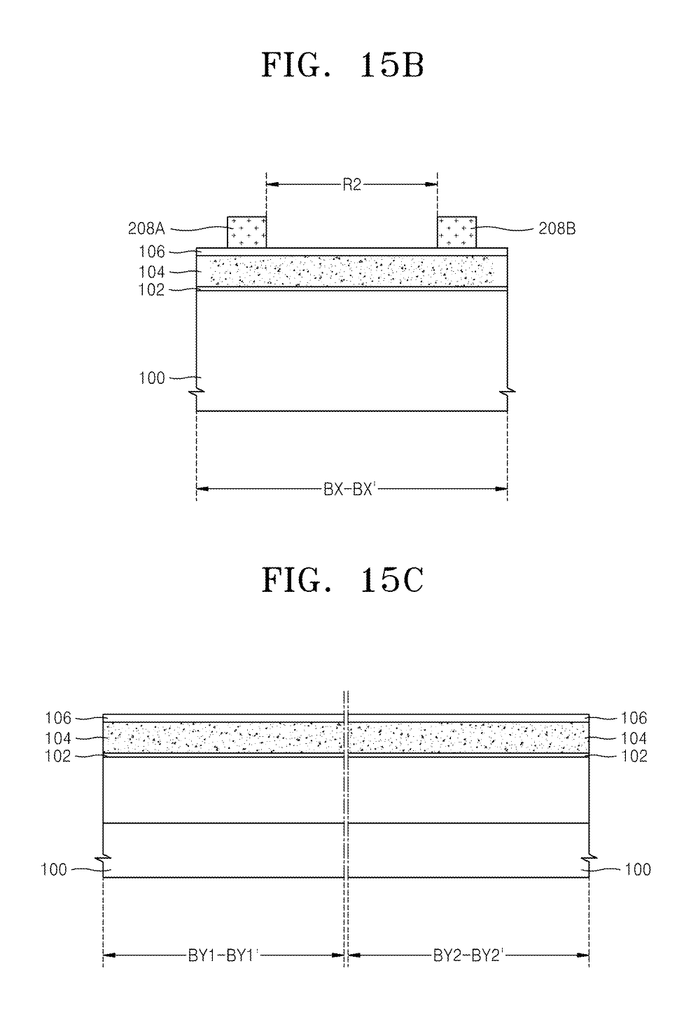

FIGS. 15A-C through FIGS. 24-24C illustrate a method of manufacturing a semiconductor device according to another embodiment of the inventive concept.

In particular, FIGS. 15A, 16A, . . . , and 24A are respectively plan views for explaining the method of manufacturing a semiconductor device illustrated in FIGS. 15A-C through FIGS. 24A-C, and FIGS. 15B, 16B, . . . , and 24B are cross-sectional views taken along lines BX-BX′ of FIGS. 15A, 16A, . . . , and 24A, and FIGS. 15C, 16C, . . . , and 24C are cross-sectional views taken along lines BY1-BY1′ and BY2-BY2′ of FIGS. 15A, 16A, . . . , and FIG. 24A, respectively.

The present embodiment that will be described with reference to FIGS. 15A-C through FIGS. 24A-4C is substantially the same as the previous embodiment described with reference to FIGS. 1A-B through FIGS. 14A-B. However, a principal difference is that, in FIGS. 15A-C through FIGS. 24A-C, a process of forming a recessed channel transistor having a relatively large gate length is illustrated and in order to connect two gate contact plugs to one gate pattern, a process of forming a gate pattern having two gate contact portions that respectively protrude from a gate portion and are separated from each other is performed.

In FIGS. 15A-C through FIGS. 24A-C, the same reference numerals as those of FIGS. 1A-B through FIGS. 14A-B refer to the same elements. For simplification of explanation, a detailed description of such elements will not be provided again.

Referring to FIGS. 15A, 15B, and 15C, a pad oxide layer 102, a first mask layer 104, an anti-reflective layer 106, and a photoresist pattern 208 are sequentially formed in the order stated on a substrate 100.

A top surface of anti-reflective layer 106 is partially exposed around photoresist pattern 208.

Photoresist pattern 208 may include two patterns 208A and 208B that respectively cover regions of substrate 100 where a pair of source/drain regions 124 (see FIGS. 18A and 18B, discussed below) of a transistor are to be formed. Patterns 208A and 208B may be formed to be separated from each other by a second distance R2 that corresponds to a distance by which the pair of source/drain regions 124 are separated from each other in a first direction which is a gate length direction (x-direction of FIG. 15A). The second distance R2 is greater than the first distance R1 between patterns 108A and 108B (see FIGS. 1A and 1B) that constitute photoresist pattern 108 in the embodiment illustrated in FIGS. 1A-B through FIGS. 14A-B.

Referring to FIGS. 16A, 16B, and 16C, anti-reflective layer 106, first mask layer 104, and pad oxide layer 102 are etched using photoresist pattern 208 as an etch mask, and an anti-reflective pattern (not shown), a first mask pattern 104A, and a pad oxide layer pattern 102A are formed, thereby exposing a top surface of substrate 100. Subsequently, the exposed substrate 100 is etched using the anti-reflective pattern (not shown) and first mask pattern 104A as an etch mask, thereby forming isolation trenches 110. After that, photoresist pattern 208 and anti-reflective pattern 106A are removed until the top surface of first mask pattern 104A is exposed.

Referring to FIGS. 17A, 17B, and 17C, an isolation layer 112A having a planarized top surface is formed in an isolation trench 110, and a channel ion implantation region 122 and a pair of source/drain regions 124 are formed in substrate 100, like in FIGS. 3A and 3B and FIGS. 4A and 4B.

An isolation layer 112A having a first width W21 in a first direction (x-direction in FIG. 17A) is formed between the pair of source/drain regions 124. Thus, a distance by which the pair of source/drain regions 124 are separated from each other in the first direction (x-direction in FIG. 17A) is equal to the first width W21. The first width W21 is greater than the first width W1 that is a separation distance between source/drain regions 124 illustrated in FIGS. 4A and 4B.

Referring to FIGS. 18A, 18B, and 18C, a second mask layer 130 is formed on isolation layer 112A and pad oxide layer pattern 102A, like in FIGS. 5A and 5B and FIGS. 6A and 6B. A third mask pattern 232, including a hole 232H for exposing portions of second mask layer 130, is formed on second mask layer 130.

A detailed description of third mask pattern 232 is substantially the same as the third mask pattern 132 described with reference to FIGS. 6A and 6B. A principal difference is that, in the present embodiment, hole 232H of third mask pattern 232 includes a first hole portion 232H1 that is formed in an upper portion of a gate region between the pair of source/drain regions 124 of substrate 100, and two second hole portions 232H2 that are formed in an upper portion of a gate contact region of substrate 100 and extend from first hole portion 232H1 in a direction away from the pair of source/drain regions 124 while communicating with first hole portion 232H1.

Each of the two second hole portions 232H2 of hole 232H of third mask pattern 232 may extend from first hole portion 232H1 in a gear tooth shape. A width DW1 (see FIG. 18A) of each of second hole portions 232H2 in a direction parallel to the first direction (x-direction in FIG. 18A) may be determined according to a thickness of a gate pattern to be formed between the pair of source/drain regions 124 in a subsequent process. For example, the width DW1 of each of the second hole portions 232H2 may be determined to be less than twice of the thickness of the gate pattern to be formed between the pair of source/drain regions 124. The reason why the width DW1 of each of the second hole portions 232H2 is determined in this manner will be described later.

First hole portion 232H1 of hole 232H formed in third mask pattern 232 has a second width W22 that is less than the first width W21 in the first direction (x-direction in FIG. 18A). Around first hole portion 232H1, portions of isolation layer 112A that are between the pair of source/drain regions 124 are covered by third mask pattern 232 by a third width W23 and a fourth width W24 in the first direction (x-direction in FIG. 18A). The second width W22 is of a similar dimension as the first width W21, and the sum of the second width W22, the third width W23, and the fourth width W24 may be the first width W21. In FIG. 18B, first hole portion 232H1 is positioned in the center of isolation layer 112A between the pair of source/drain regions 124 so that the third width W23 and the fourth width W24 may be the same. However, aspects of the inventive concept are not limited thereto. The third width W23 and the fourth width W24 may have different dimensions according to the position of first hole portion 232H1 between the pair of source/drain regions 124.

Referring to FIGS. 19A, 19B, and 19C, second mask layer 130 is anisotropically etched using third mask pattern 232 as an etch mask, thereby forming a second mask pattern 130A for exposing isolation layer 112A. Subsequently, isolation layer 112A exposed through second mask pattern 130A is anisotropically etched, thereby forming a gate trench 240 in isolation layer 112A.

After that, third mask pattern 232 that remains on second mask pattern 130A is removed until a top surface of second mask pattern 130A is exposed.

Gate trench 240 has a depth that is less than that of isolation trench 110. In particular, a distance from the top surface of substrate 100 where source/drain regions 124 are formed to a bottom surface of gate trench 240 is less than a distance from the top surface of substrate 100 where source/drain regions 124 are formed to a bottom surface of isolation trench 110. Thus, only isolation layer 112A may be exposed as inner walls of gate trench 240.

Gate trench 240 includes a first gate trench portion 240T1 in which a gate portion 252G (see FIGS. 22A, 22B, and 22C, discussed below) between the pair of source/drain regions 124 of substrate 100 is to be disposed, and two second gate trench portions 240T2 in which gate contact portions 252C1 and 252C2 (see FIGS. 22A, 22B, and 22C, discussed below) of substrate 100 are respectively to be disposed and which extend from first gate trench portion 240T1 in a direction away from the pair of source/drain regions 124, while communicating with (i.e., being connected to) first gate trench portion 240T1.

In gate trench 240, each of the two second gate trench portions 240T2 may extend from first gate trench portion 240T1 in a gear tooth shape. A width DW2 (see FIG. 19A) of each of the second gate trench portions 240T2 in a direction parallel to a first direction (x-direction in FIG. 19A) may be determined according to a thickness of a gate pattern to be formed between the pair of source/drain regions 124 in a subsequent process. For example, the width DW2 of each of the second gate trench portions 240T2 may be determined to be less than twice of the thickness of the gate pattern to be formed between the pair of source/drain regions 124. The reason why the width DW2 of each of the second gate trench portions 240T2 is determined in this manner will be described later.

Referring to FIGS. 20A, 20B, and 20C, a mask spacer 142 is formed on inner sidewalls of gate trench 240, like in FIGS. 8A and 8B and FIGS. 9A and 9B. The mask spacer 142 may be formed of silicon nitride (SiN). After that, isolation layer 112A exposed by mask spacer 142 is removed from gate trench 240 by using a wet etching process until substrate 100 is exposed to a bottom surface of gate trench 240 and a lower portion of sidewalls of gate trench 240, so that a lower portion of gate trench 240 may be increased in both vertical and horizontal directions to form a lower portion 240BT of gate trench 240 which is extended in vertical and horizontal directions.

Portions of isolation layer 112A that cover source/drain regions 124 and are close to the top surface of substrate 100 are protected by mask spacer 142 on inner sidewalls of gate trench 240 and remain as remaining portions 112B of isolation layer 112A. Due to remaining portions 112B, a separation distance between an internal space of gate trench 240 and top surfaces of the source/drain regions 124 may be obtained.

In FIG. 20A, a planar shape of lower portion 240BT that extends in vertical and horizontal directions is indicated by a dashed line.

Referring to FIGS. 21A, 21B, and 21C, first mask pattern 130A and mask spacer 142 are removed, like in FIGS. 10A and 10B.

Referring to FIGS. 22A, 22B, and 22C, after an insulating layer 250 for forming a gate insulating layer 250A is formed on the surface of substrate 100 exposed in lower portion 240BT of gate trench 240 and a gate conductive layer (not shown) is formed on insulating layer 250 so as to be filled in gate trench 240, the gate conductive layer is planarized until isolation layer 112A and remaining portions 112B of isolation layer 112A are exposed, thereby forming a gate pattern 252 positioned only in gate trench 240, like in FIGS. 11A and 11B and FIGS. 12A and 12B. In order to planarize the gate conductive layer, a CMP process may be used.

Portions of the pair of source/drain regions 124 exposed at the inner walls of isolation trench 110 contact remaining portions 112B of isolation layer 112A, and portions of the pair of source/drain regions 124 exposed at the bottom sidewalls of isolation trench 110 contact gate insulating layer 250A.

Insulating layer 250 for forming gate insulating layer 250A may be a silicon oxide layer, for example.

Gate pattern 252 may be formed of an electrically conductive material. Gate pattern 252 may be formed of doped polysilicon, metal, metal nitride, metal silicide or a combination thereof.

Gate pattern 252 includes a gate portion 252G that is positioned in first gate trench portion 240T1 and functions as a gate electrode between the pair of source/drain regions 124, and two gate contact portions 252C1 and 252C2 that are respectively positioned in second gate trench portions 240T2 and extend from gate portion 252G in a direction away from the pair of source/drain regions 124 while being integrally formed with gate portion 252G as one contiguous unit. As illustrated in FIGS. 22A, 22B, and 22C, gate contact portions 252C1 and 252C2 may be arranged in a line in a first direction which is a gate length direction (x-direction in FIG. 22A) of gate pattern 252 and may have a gear tooth shape that extend from gate portion 252G.

The planarized top surface of gate pattern 252, including gate portion 252G and gate contact portions 252C1 and 252C2, may be at the same level as (i.e., be substantially planar with) the top surface of isolation layer 112A and the top surface of remaining portions 112B of isolation layer 112A.

Gate pattern 252 may be formed to have a uniform first thickness TH1 at the sidewalls of gate trench 240 and at the bottom surface of lower portion 240BT of gate trench 240. The first thickness TH1 may be greater than half of the width DW2 of each of the second gate trench portions 240T2. When the first thickness TH1 and the width DW2 of each of the second gate trench portions 240T2 are provided in this manner, a width GX21 and a depth of first gate trench portion 240T1 of gate trench 240 in the first direction (x-direction in FIG. 22A) are relatively large. Thus, after gate pattern 252 is formed, an internal space of first gate trench portion 240T1 is not completely filled by gate portion 252G of gate pattern 252, and there may be an empty space in gate portion 252G, in an inlet center of first gate trench portion 240T1. Since the width DW2 of each of second gate trench portions 240T2 in a direction parallel to first direction (x-direction in FIG. 22A) is less than twice of first thickness TH1, internal spaces of second gate trench portions 240T2, after gate pattern 252 is formed, are respectively completely filled by gate contact portions 252C1 and 252C2 of gate pattern 252.

As illustrated in FIGS. 22B and 22C, gate portion 252G of gate pattern 252 may be “ [symbol] ”-shaped when viewed in a cross-section taken in the first direction (x-direction in FIG. 22A). As illustrated in a cross-section taken along the line BY2-BY2′ of FIG. 22C, gate portion 252G of gate pattern 252 in a portion where gate contact portions 252C1 and 252C2 are not formed, may be “ [symbol] ”-shaped when viewed in a cross-section taken in a direction perpendicular to the first direction (y-direction in FIG. 22A).

Due to remaining portions 112B of isolation layer 112A that cover source/drain regions 124 as the inner walls of first gate trench portion 240T1 of gate trench 240, a separation distance between gate portion 252G of gate pattern 252 and top surfaces of the source/drain regions 124 may be obtained.

Referring to FIGS. 23A, 23B, and 23C, an interlayer insulating layer 260 is formed on the resultant structure in which gate pattern 252 is formed, and interlayer insulating layer 260 and portions of pad oxide layer pattern 102A under interlayer insulating layer 260 are anisotropically etched, thereby forming a plurality of contact holes 260H formed through interlayer insulating layer 260.

The plurality of contact holes 260H may include two gate contact holes 260H1 for respectively exposing gate contact portions 252C1 and 252C2, and a pair of source/drain contact holes 260H2 for respectively exposing portions of the top surfaces of the pair of source/drain regions 124.

Referring to FIGS. 24A, 24B, and 24C, a plurality of contact plugs 270 are formed in the plurality of contact holes 260H, like in FIGS. 14A and 14B.

The plurality of contact plugs 270 may include two gate contact plugs 270G1 and 270G2 respectively connected to gate contact portions 252C1 and 252C2, and a pair of source/drain contact plugs 270C respectively connected to the top surfaces of the pair of source/drain regions 124.

A detailed process of forming the plurality of contact plugs 270 is similar to the process of forming the plurality of contact plugs 170 described with reference to FIGS. 14A and 14B.

After that, although not shown, metal interconnection layers respectively connected to contact plugs 270 may be formed on interlayer insulating layer 260.

In the semiconductor device manufactured using the method of FIGS. 15A-C through FIGS. 24A-C, gate portion 252G of gate pattern 252 is at a lower level than the top surface of substrate 100 where source/drain regions 124 are formed, and thus a transistor having a recessed channel structure is formed. Thus, the channel length of the transistor can be remarkably increased. Even in the case of a highly integrated semiconductor device, stable device characteristics may be obtained. Also, gate contact portions 252C1 and 252C2, to which gate contact plugs 270G1 and 270G2 for applying a voltage to gate portion 252G are respectively connected, extend from gate portion 252G. Gate contact portions 252C1 and 252C2 with smaller widths than a width of gate portion 252G are separated from each other. Gate contact portions 252C1 and 252C2 include portions of gate pattern 252. Thus, top surfaces of gate contact portions 252C1 and 252C2 are respectively planarized at the same level as that of isolation layer 112A.

Since gate contact portions 252C1 and 252C2 are formed simultaneously with gate portion 252G, an additional process of forming gate contact portions 252C1 and 252C2 is not necessary. Thus, a method of manufacturing a semiconductor device, which includes a process of forming a recessed channel transistor, may be simplified.

Also, due to remaining portions 112B of isolation layer 112A that cover the pair of source/drain regions 124 as the inner walls of first gate trench portion 240T1 of gate trench 240, a separation distance between gate portion 252G of gate pattern 252 and the source/drain contact plugs 270C connected to the top surfaces of the pair of source/drain regions 124 may be obtained. Thus, even when a high voltage is applied to a drain terminal of the pair of source/drain regions 124, a sufficient distance between a drain region and a recessed channel region is obtained so that breakdown may be prevented and a high breakdown voltage may be sustained.

In the method of manufacturing a semiconductor device illustrated in FIGS. 15A-C through FIGS. 24A-C, gate pattern 252 having a relatively large gate length that is the length of gate portion 252G in a channel direction is formed. Gate contact plugs 270G1 and 270G2 are formed in gate pattern 252, and in order to connect gate contact plugs 270G1 and 270G2 to gate pattern 252, a gate pattern 252 is formed which has gate contact portions 252C1 and 252C2 that respectively protrude from gate portion 252G and are separated from each other. However, aspects of the inventive concept are not limited thereto. In particular, a gate pattern in which three or more gate contact portions are connected to a gate portion may be formed.

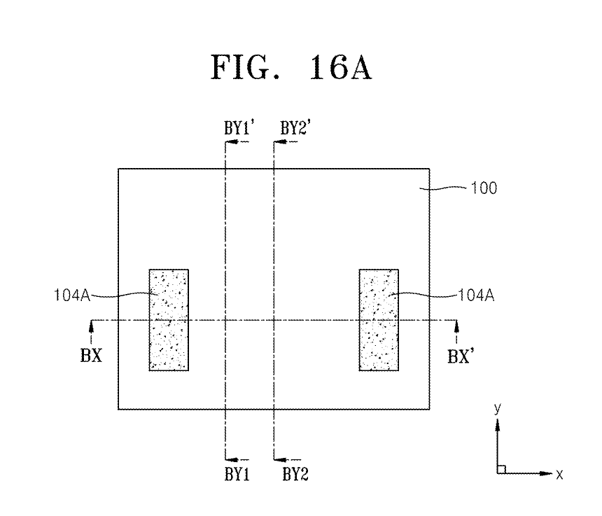

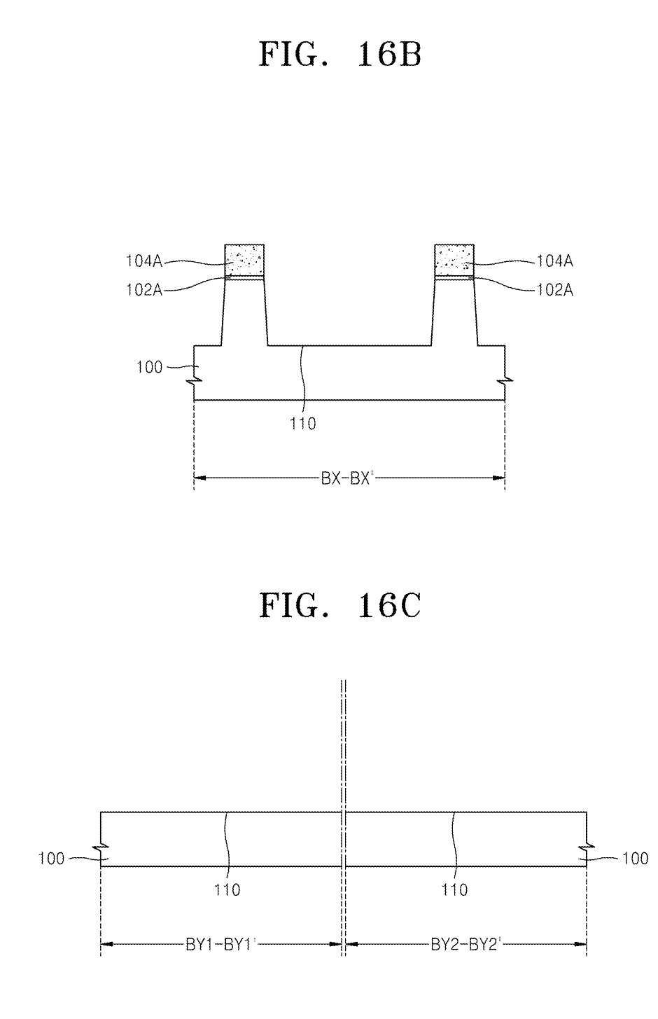

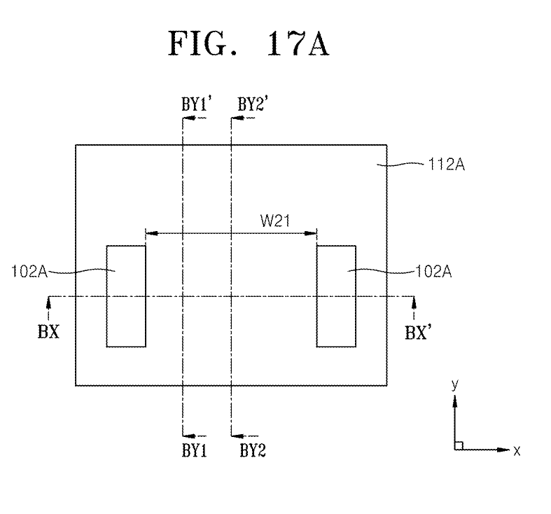

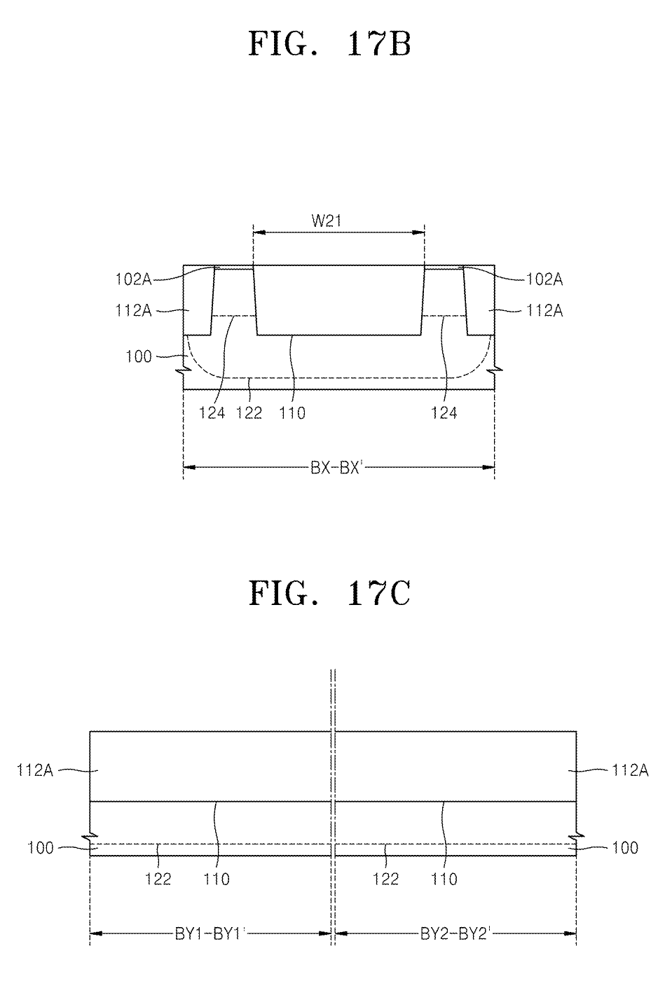

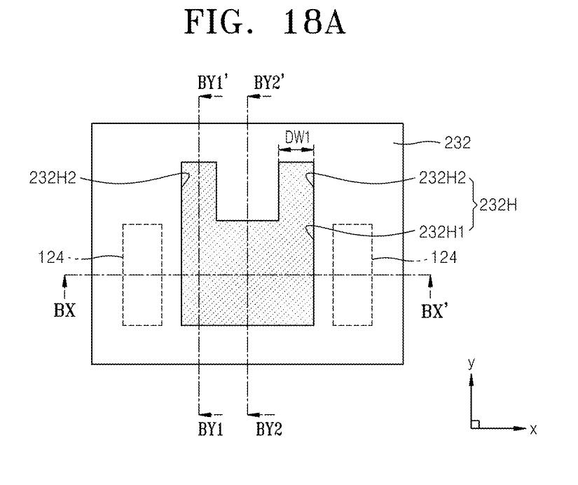

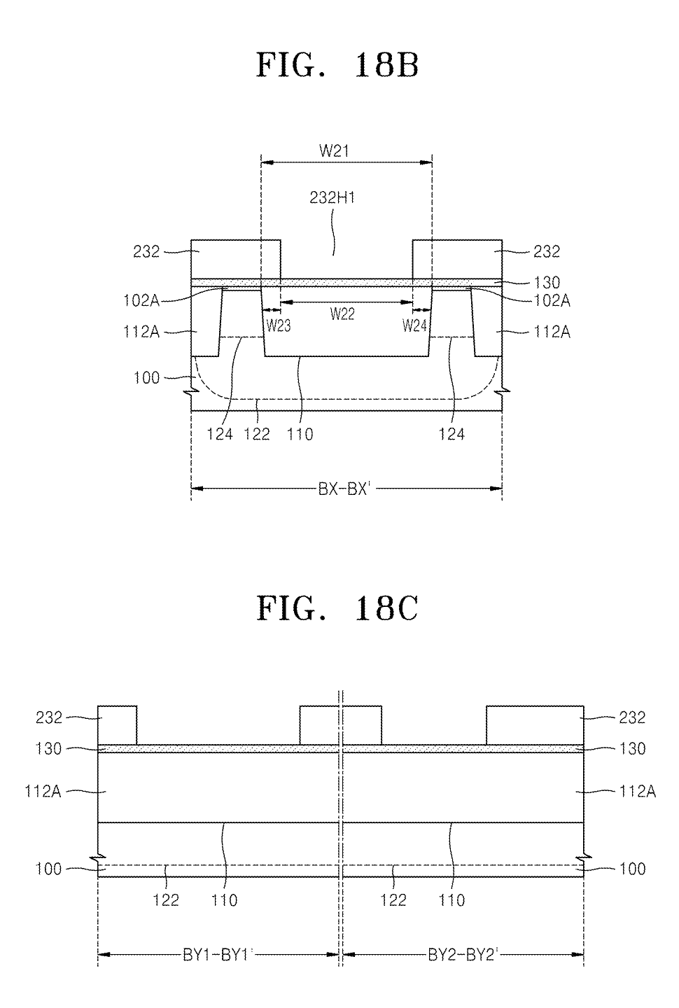

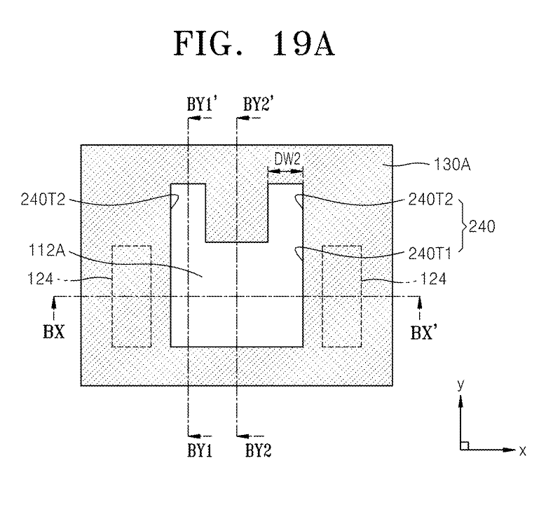

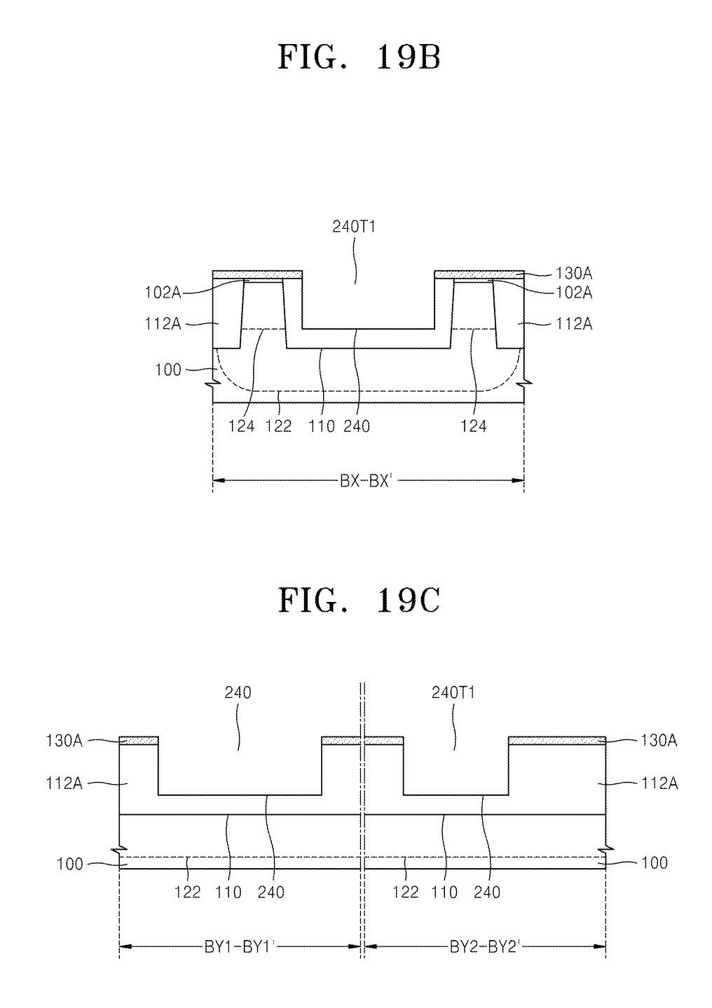

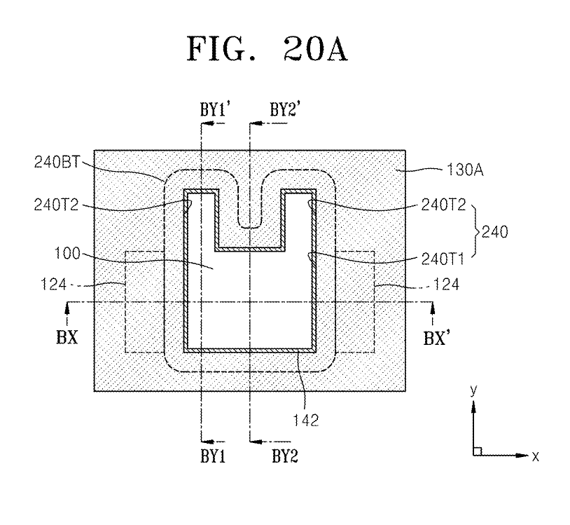

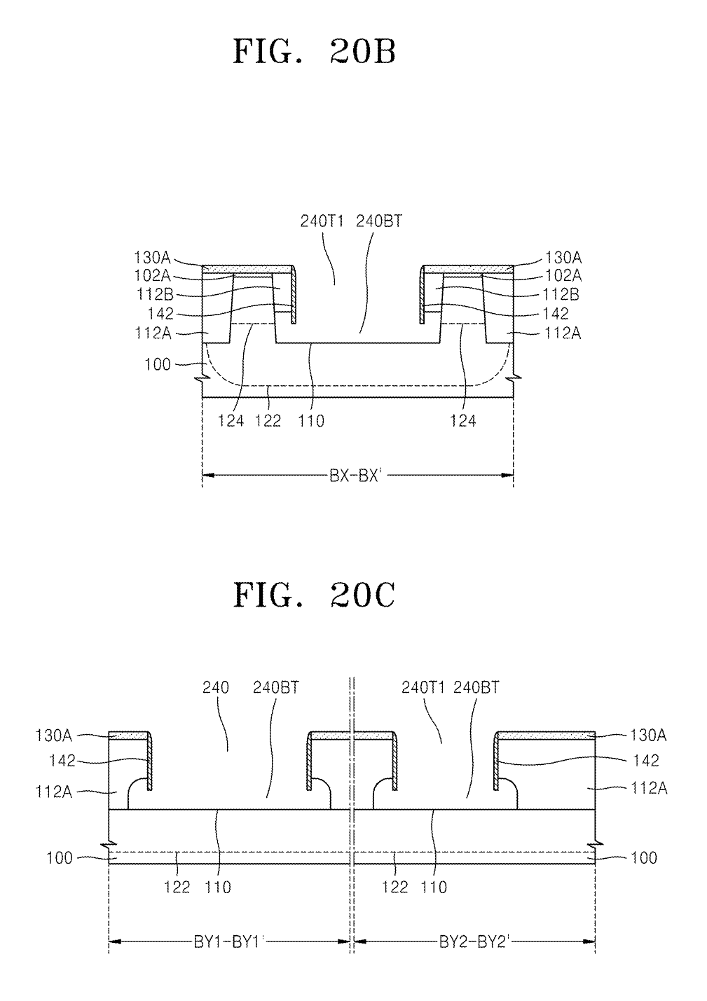

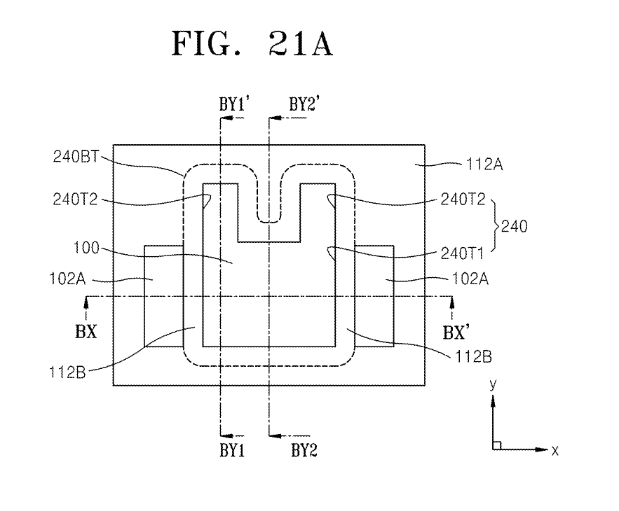

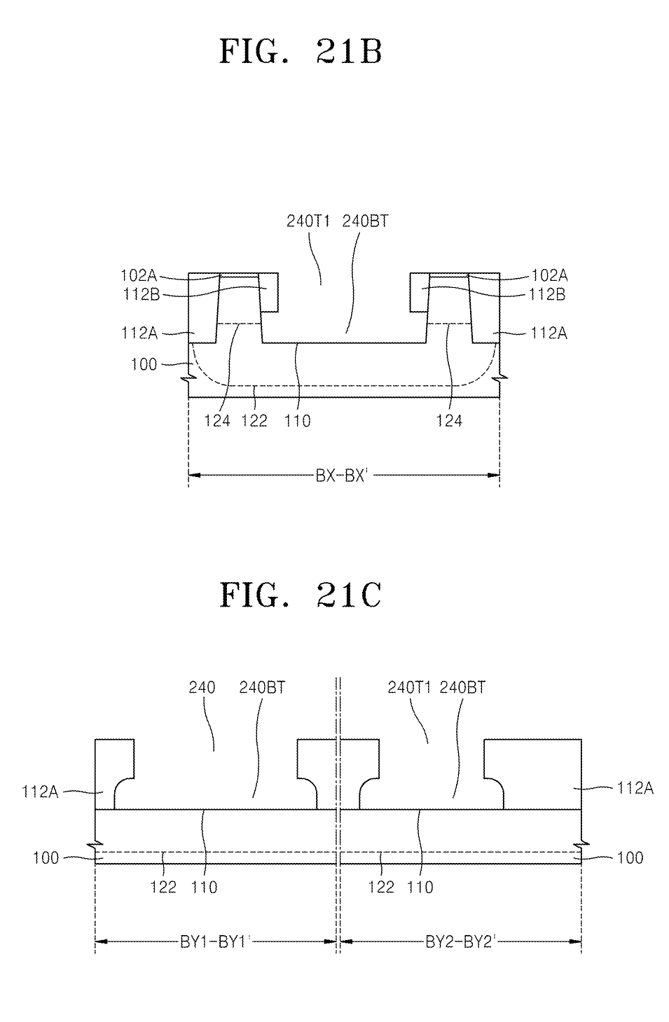

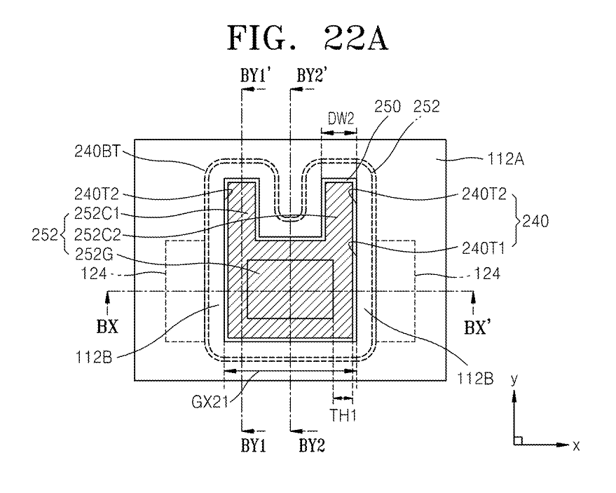

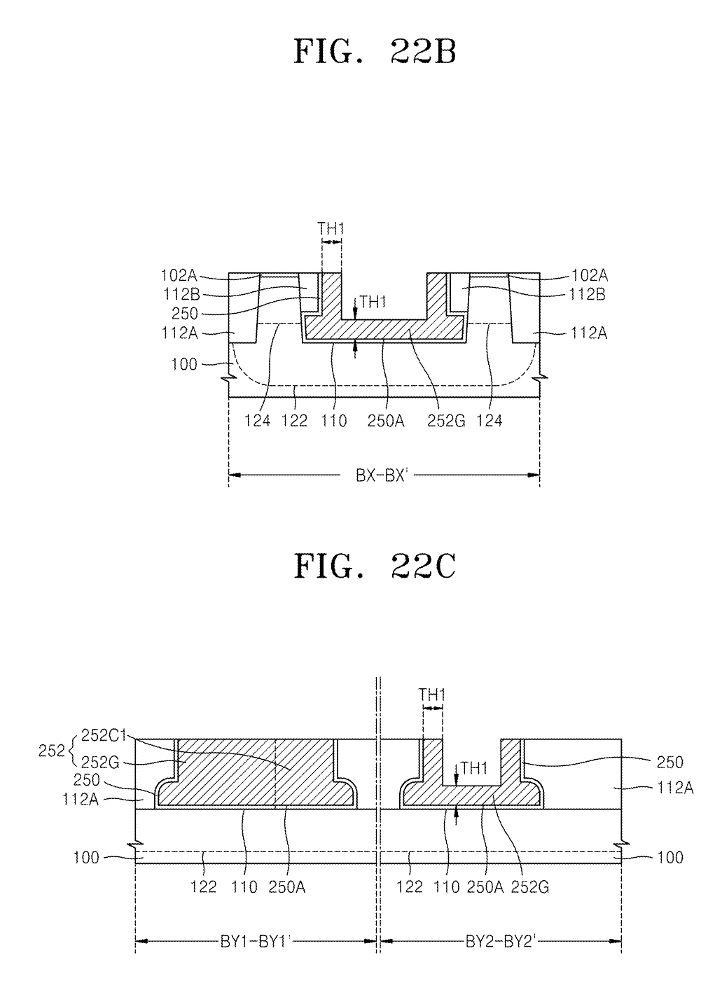

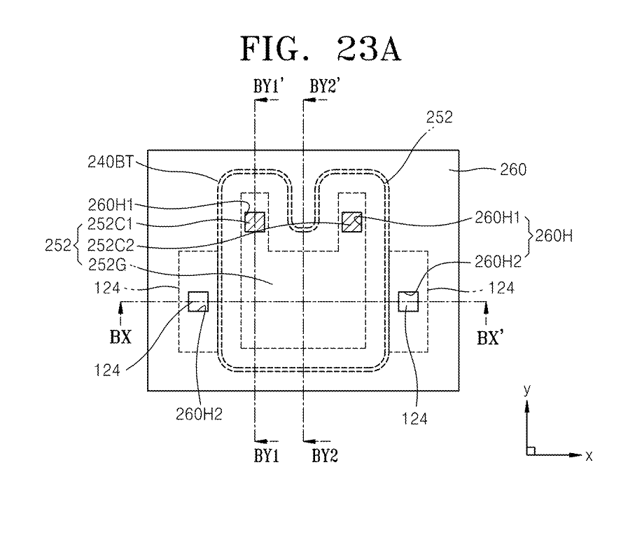

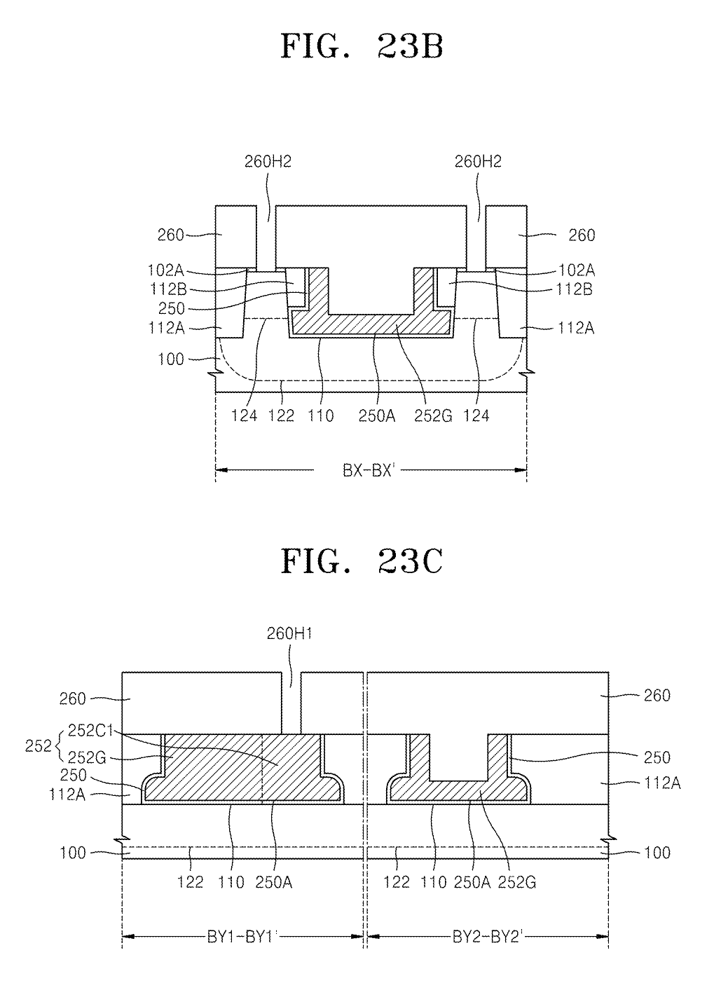

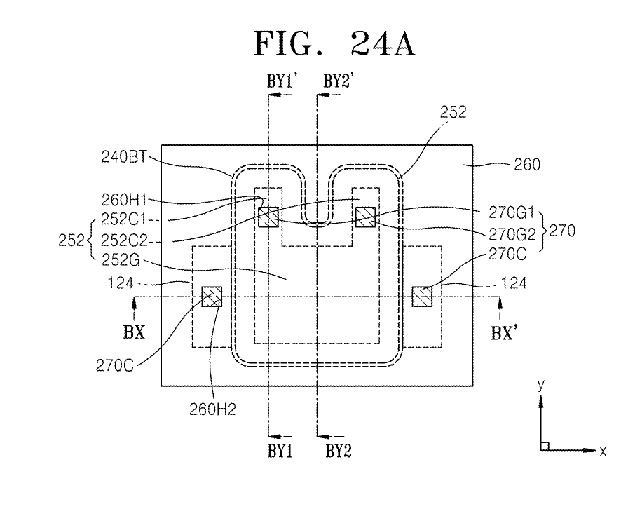

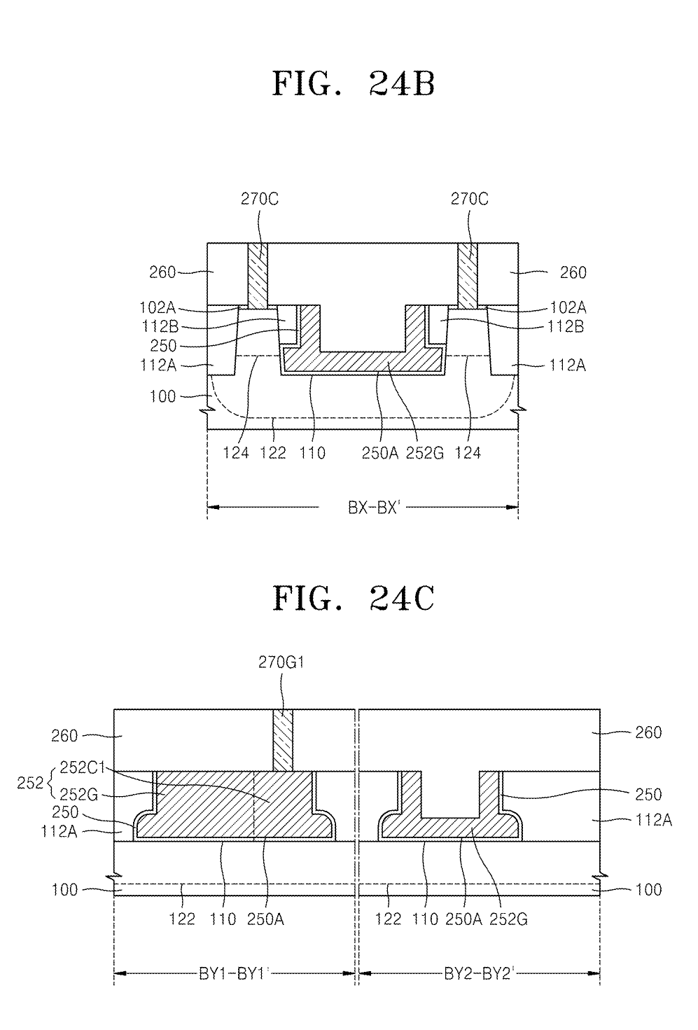

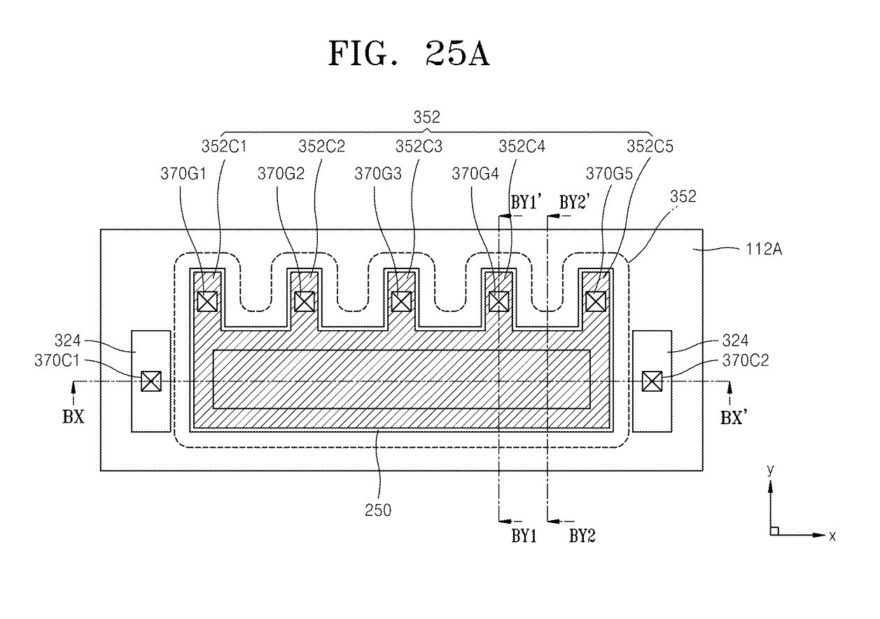

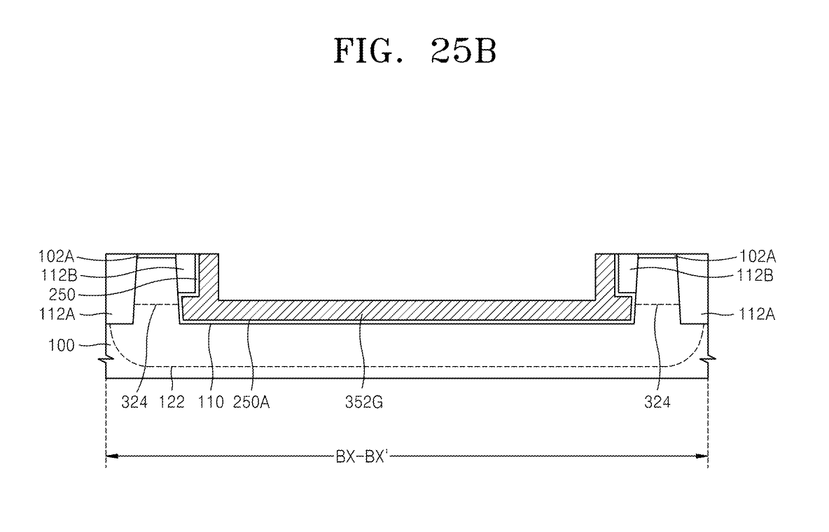

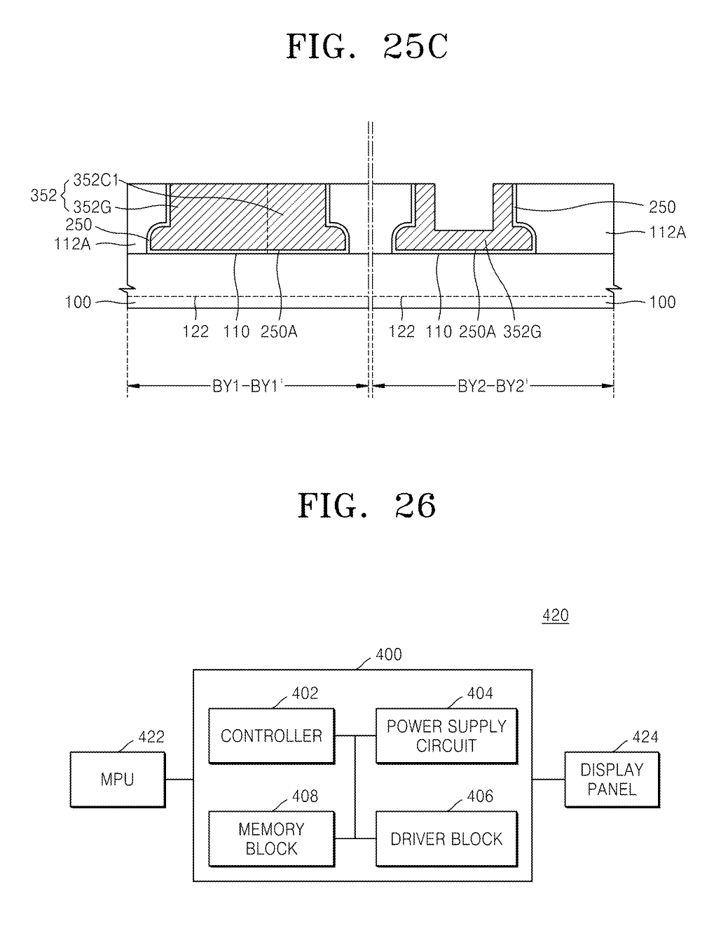

FIGS. 25A, 25B, and 25C illustrate relevant portions of a structure of a semiconductor device according to another embodiment of the inventive concept.

In particular, FIG. 25A is a plan view of a recessed channel transistor including a gate pattern 352 having five gate contact portions 352C1, 352C2, 352C3, 352C4, and 352C5, and FIG. 25B is a cross-sectional view taken along a line BX-BX′ of FIG. 25A, and FIG. 25C is a cross-sectional view taken along lines BY1-BY1′ and BY2-BY2′ of FIG. 24A, respectively.

In FIGS. 25A, 25B, and 25C, the same reference numerals as those of FIGS. 15A-C through FIGS. 24A-C refer to the same elements. For simplification of explanation, a detailed description thereof will not be repeated.

Referring to FIGS. 25A, 25B, and 25C, gate pattern 352 includes a gate portion 352G disposed between a pair of source/drain regions 324, and five gate contact portions 352C1, 352C2, 352C3, 352C4, and 352C5 that respectively protrude from gate portion 352G and are separated from one another. Gate contact portions 352C1, 352C2, 352C3, 352C4, and 352C5 extend from gate portion 352G in a direction away from source/drain regions 324 while being integrally formed with gate portion 352G as one contiguous unit. As illustrated in FIGS. 25A, 25B, and 25C, gate contact portions 352C1, 352C2, 352C3, 352C4, and 352C5 may be arranged in a line in a direction parallel to the first direction (x-direction in FIG. 25A) and may have a gear tooth shape that extends from gate portion 352G.

A plurality of contacts 370G1, 370G2, 370G3, 370G4, and 370G5 for applying voltages to gate portion 352G may be formed in gate contact portions 352C1, 352C2, 352C3, 352C4, and 352C5. Source/drain contacts 370C1 and 370C2 for applying voltages to source/drain regions 324 may be formed in the pair of source/drain regions 324.

Due to remaining portions 112B of isolation layer 112A interposed between the pair of source/drain regions 324 and gate portion 352G, a separation distance between gate portion 352G of gate pattern 352 and source/drain contacts 370C1 and 370C2 formed in the pair of source/drain regions 324 may be obtained. Thus, even when a high voltage is applied to a drain terminal of the pair of source/drain regions 324, a sufficient distance between a drain region and a recessed channel region is obtained so that breakdown may be prevented and a high breakdown voltage may be sustained.

A detailed process of forming a transistor including gate pattern 352 including gate contact portions 352C1, 352C2, 352C3, 352C4, and 352C5 illustrated in FIGS. 25A, 25B, and 25C is substantially the same as the previous embodiment illustrated in FIGS. 15A, 15B, and 15C through FIGS. 24A, 24B, and 24C and thus a detailed description thereof will not be provided here.

Transistors included in semiconductor devices described with reference to FIGS. 1A-B through FIGS. 25A-C may be high-voltage transistors or low-voltage transistors that constitute a digital circuit or an analog circuit. For example, transistors included in semiconductor devices according to the inventive concept may constitute high-voltage transistors that constitute peripheral circuits of a flash memory device that is a nonvolatile memory device operating with a high voltage or an electrically erasable and programmable read only memory (EEPROM) device. Alternatively, a transistor included in a semiconductor device according to aspects of the present invention may be a transistor included in a liquid crystal display (LCD) integrated circuit (IC) device that requires an operating voltage of 10 V or more, for example, in the range of 20 to 30 V or an IC chip used in a plasma display panel (PDP) that requires an operating voltage of 100 V.

FIG. 26 is a schematic block diagram of a display driver integrated circuit (IC) (DDI) 400 and a display apparatus 420 including DDI 400, according to an embodiment of the inventive concept, and a display panel 424.

Referring to FIG. 26, DDI 400 may include a controller 402, a power supply circuit 404, a driver block 406, and a memory block 408. Controller 402 performs decoding by receiving a command given by a main processing unit (MPU) 422 and controls blocks of DDI 400 so as to perform an operation according to a command. Power supply circuit 404 generates a driving voltage in response to control performed by controller 402. Driver block 406 may drive display panel 424 by using a driving voltage generated by power supply circuit 404 in response to control performed by controller 402. Display panel 424 may be an LCD panel or a PDP or other suitable display panel. Memory block 408 temporarily stores the command input to controller 402 and/or control signals output from controller 402 and/or necessary data, and may include a memory such as a random access memory (RAM), a read only memory (ROM) or the like. Power supply circuit 404 and driver block 406 may include one or a plurality of semiconductor devices among the semiconductor devices illustrated in FIGS. 1A and 1B through FIGS. 25A, 25B, and 25C.

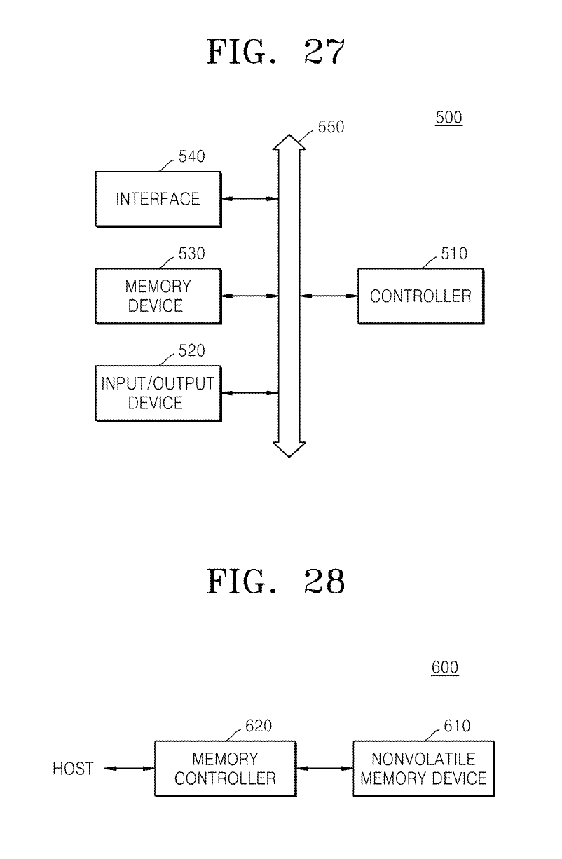

FIG. 27 is a schematic block diagram of a structure of an electronic system 500 according to an embodiment of the inventive concept.

Referring to FIG. 27, electronic system 500 may include a controller 510, an input/output device 520, a memory device 530, and an interface 540. Controller 510, input/output device 520, memory device 530, and interface 540 are connected to one another to allow data transmission and reception via a bus 550. Controller 510 may include one or a plurality of semiconductor devices among the semiconductor devices illustrated in FIGS. 1A and 1B through FIGS. 25A, 25B, and 25C.

Input/output device 520 may include at least one selected from a keypad, a keyboard, and a display device. Memory device 530 may store data, a command executed by controller 510, and the like. Memory device 530 may include one or a plurality of semiconductor devices among the semiconductor devices illustrated in FIGS. 1A and 1B through FIGS. 25A, 25B, and 25C. Interface 540 may be a wireless or wired interface for transmitting or receiving data to or from a communication network. For example, interface 540 may include an antenna, a wired/wireless transceiver or the like.

Electronic system 500 may be implemented as a mobile system, a personal computer (PC), an industrial computer, a system having various functions, or the like. For example, the mobile system may be a personal digital assistant (PDA), a portable computer, a web tablet, a mobile phone, a wireless phone, a laptop computer, a memory card, a digital music system, an information transmission/reception system, or the like. When electronic system 500 is equipment for performing wireless communication, electronic system 500 may be used in a communication interface protocol, such as a three-generation communication system, such as code division multiple access (CDMA), global system for mobile communications (GSM), NADC, E-TDMA, WCDAM, and CDMA2000.

FIG. 28 is a schematic block diagram of a structure of a memory card 600 according to an embodiment of the inventive concept.

Referring to FIG. 28, memory card 600 may include a nonvolatile memory device 610 and a memory controller 620. Nonvolatile memory device 610 may store data and/or read the stored data. Nonvolatile memory device 610 may include one or a plurality of semiconductor devices among the semiconductor devices illustrated in FIGS. 1A and 1B through FIGS. 25A, 25B, and 25C. Memory controller 620 may control nonvolatile memory device 610 to read the stored data or to store the data in response to a read/write request of a host.

While the inventive concepts have been particularly shown and described with reference to exemplary embodiments thereof, it will be understood that various changes in form and details may be made therein without departing from the spirit and scope of the following claims.

1. A semiconductor device comprising:
a substrate having an isolation trench therein;
an isolation layer in the isolation trench so as to define a pair of source/drain regions in the substrate;
a gate pattern in the isolation trench between the pair of source/drain regions, the gate pattern having a top surface at a same level as a top surface of the isolation layer and having a bottom surface at a lower depth than the pair of source/drain regions with respect to a top surface of the substrate; and
a gate insulating layer provided between the substrate and the gate pattern at a bottom surface of the isolation trench.

2. The semiconductor device of claim 1, wherein the gate pattern comprises:
a gate portion positioned between the pair of source/drain regions; and
at least one gate contact portion extending from the gate portion in a direction away from the pair of source/drain regions while being integrally formed with the gate portion as one contiguous unit,
wherein a top surface of the gate portion and a top surface of the at least one gate contact portion are at the same level as the level of the top surface of the isolation layer.

3. The semiconductor device of claim 2, wherein the gate pattern further comprises at least one gate contact plug connected to the at least one gate contact portion so as to apply a voltage to the gate portion.

4. The semiconductor device of claim 2, wherein the gate portion and the at least one gate contact portion have a “⊥”-shaped cross-section, respectively.

5. The semiconductor device of claim 2, wherein the gate portion has a “ [symbol] ”-shaped cross-section.

6. The semiconductor device of claim 2, wherein the gate pattern is formed in a gate trench formed through the isolation layer in the isolation trench, and an inlet width of the gate trench between the pair of source/drain regions is less than an inlet width of the isolation trench.

7. The semiconductor device of claim 6, wherein the isolation layer comprises a first isolation layer portion that covers the pair of source/drain regions as inner walls of the isolation trench, and the inlet width of the gate trench is defined by the first isolation layer portion.

8. The semiconductor device of claim 7, wherein the inlet width of the gate trench is less than a width of a bottom surface of the gate trench in a direction extending between the pair of source/drain regions.

9. The semiconductor device of claim 7, wherein portions of the pair of source/drain regions exposed at a top portion of inner sidewalls of the isolation trench contact the first isolation layer, and portions of the pair of source/drain regions exposed at a bottom portion of the inner sidewalls of the isolation trench contact the gate insulating layer.

10. The semiconductor device of claim 6, wherein the gate trench comprises:
a first gate trench portion in which the gate portion is positioned; and
at least one second gate trench portion in which the at least one gate contact portion is positioned and which extends from the first gate trench portion in a direction away from the pair of source/drain regions while communicating with the first gate trench portion, and
wherein the gate portion completely fills the first gate trench portion on the gate insulating layer, and the at least one gate contact portion completely fills the at least one second gate trench portion on the gate insulating layer.

11. The semiconductor device of claim 6, wherein the gate pattern comprises the gate portion and a plurality of gate contact portions, and
wherein the gate trench comprises:
a first gate trench portion in which the gate portion is positioned; and
a plurality of second gate trench portions in which the plurality of gate contact portions are respectively positioned and which extend from the first gate trench portion in a direction away from the pair of source/drain regions while communicating with the first gate trench portion, and
wherein the gate portion completely fills remaining portions of the first gate trench portion excluding an inlet center of the first gate trench portion on the gate insulating layer, and the plurality of gate contact portions completely fill the plurality of second gate trench portions on the gate insulating layer.

12. The semiconductor device of claim 11, wherein the plurality of gate contact portions are arranged in a line in a first direction, and the plurality of gate contact portions extend from the gate portion in a gear tooth shape.

13. The semiconductor device of claim 11, further comprising an insulating layer filling the inlet center of the first gate trench portion on the gate portion.

14. A semiconductor device comprising:
a substrate in which an isolation trench is provided;
an isolation layer provided in the isolation trench so as to define a pair of source/drain regions in the substrate;
a gate pattern provided in a gate trench formed through the isolation layer in an isolation trench, the gate trench having a top surface at a same level as a top surface of the isolation layer and comprising a gate portion positioned between the pair of source/drain regions in the gate trench, and at least one gate contact portion extending from the gate portion in a direction away from the gate portion while being integrally formed with the gate portion as one contiguous unit in the gate trench; and
a gate insulating layer provided between the substrate and the gate pattern.

15. The semiconductor device of claim 14, further comprising:
at least one gate contact plug connected to the at least one gate contact portion so as to apply a voltage to the gate portion; and
a pair of source/drain contact plugs respectively connected to the pair of source/drain regions so as to apply voltages to the pair of source/drain regions.

16. The semiconductor device of claim 14, wherein top surfaces of the pair of source/drain regions are separated from the gate portion with a first isolation layer portion that is part of the isolation layer interposed therebetween.

17. The semiconductor device of claim 16, wherein an upper portion of the gate pattern that is at a top surface of the substrate is surrounded by the first isolation layer portion with the gate insulating layer interposed therebetween.

18. The semiconductor device of claim 16, wherein a lower portion of the gate pattern that is further away from the top surface of the substrate than an upper portion of the gate pattern has a larger width than a width of the upper portion of the gate pattern.

19. The semiconductor device of claim 14, wherein the gate trench comprises:
a first gate trench portion in which the gate portion is positioned;
at least one second gate trench portion in which the at least one gate contact portion is positioned and which extends from the first gate trench portion in a direction away from the pair of source/drain regions while being in contact with the first gate trench portion, and
wherein the gate portion fills at least part of the first gate trench portion on the gate insulating layer, and the at least one gate contact portion completely fills the at least one second gate trench portion on the gate insulating layer.

20. The semiconductor device of claim 14, wherein the gate pattern comprises the gate portion and a plurality of gate contact portions, and
wherein the gate trench comprises:
a first gate trench portion in which the gate portion is positioned; and
a plurality of second gate trench portions in which the plurality of gate contact portions are respectively positioned and which extend from the first gate trench portion in a direction away from the pair of source/drain regions while being in contact with the first gate trench portion, and
wherein the gate portion completely fills remaining portions of the first gate trench portion excluding an inlet center of the first gate trench portion on the gate insulating layer, and the plurality of gate contact portions completely fill the plurality of second gate trench portions on the gate insulating layer.

21-40. (canceled)
